(19) United States
(12) Patent Application Publication
(10) Pub. No.: US 2019/0002604 A1
(43) Pub. Date: Jan. 3, 2019

(54) HETERORING-CONTAINING SILOXANE POLYMER, COMPOSITION CONTAINING SAID POLYMER, AND ELECTRONIC ELEMENT

(71) Applicant: DIC Corporation, Tokyo (JP)

(72) Inventors: Eiji OTSUKI, Chiba (JP); Yuusaku GOTOU, Chiba (JP)

(21) Appl. No.: 16/063,229

(22) PCT Filed: Aug. 19, 2016
(86) PCT No.: PCT/JP2016/074229

§ 371 Date: Jun. 15, 2018

(30) Foreign Application Priority Data
Dec. 16, 2015 (JP) 2015-245281

(51) Int. Cl. C08F 12/32; H01L 51/00

(52) U.S. Cl. CPC C08F 12/32; H01L 51/5012; H01L 51/0094

(57) ABSTRACT

An object of the present invention is to provide a novel hetero ring-containing siloxane polymer, a composition and an electronic material composition containing the polymer, and an electronic element, which do not cause a decrease in luminous efficiency and driving stability of an electronic element, by adding the polymer to an electronic material composition or ink to be used for coating film formation. It has been found that the electronic element produced from the novel hetero ring-containing siloxane polymer, the composition and the electronic material composition containing the polymer exhibit improved luminous efficiency and driving stability, thereby completing the present invention.

### TECHNICAL FIELD

The present invention relates to a hetero ring-containing siloxane polymer, a composition and an electronic material composition containing the polymer, and an electronic element containing the electronic material composition.

### BACKGROUND ART

In recent years, researches on electronic elements such as TFTs, solar cells, and organic electroluminescence elements have been conducted in various ways. In the related art, these electronic elements have been prepared by vacuum film formation, but in recent years, due to the demand on increasing the area of the substrate and reducing the cost of the product, attention has been paid to methods of preparing electronic elements by printing.

These electronic elements can be roughly classified into a low molecular weight material and a high molecular weight material on the basis of the forming materials.

Regarding the low molecular weight electronic material, in addition to the vacuum film formation, which has been used in the related art, research and development of techniques for forming a film containing an electronic material by using various coating methods such as inkjet, nozzle jet, flexographic printing, and transfer method have been carried out recently. On the other hand, since vacuum film formation is not suitable for the high molecular weight electronic material due to the large molecular weight, the above-mentioned coating method is mainly used as in the low molecular weight material.

Since the semiconductor film obtained through coating film formation is inferior in smoothness compared to that obtained through the vacuum film formation, and exhibits deteriorated electronic element characteristics, a leveling agent for forming an organic semiconductor-containing layer, with which a semiconductor-containing layer with excellent flatness for an electronic element can be formed, and a method of using the same, a composition and ink for forming an organic semiconductor-containing layer, and an organic device and a method of producing the same have been studied, and for example, PTL 1 discloses a leveling agent for forming an organic semiconductor-containing layer containing a polyether-modified polysiloxane, an aralkyl-modified polysiloxane, a silicon-modified (meth)acrylic polymer, or a (meth)acrylic-modified polysiloxane.

### CITATION LIST

### Patent Literature

[PTL 1] JP-A-2014-205830

### SUMMARY OF INVENTION

### Technical Problem

The coating film obtained according to the invention described in PTL 1 may have a certain level of flatness due to a leveling effect. Nonetheless, the presence of the polyether group and aralkyl group in a polyether-modified siloxane and aralkyl-modified siloxane, and the carbonyl group, which is a group exhibiting polarity, in a (meth)acrylic polymer, may inhibit the charge transfer, which causes a concern that the luminous efficiency or driving stability of an electronic element may be deteriorated. Consequently, there may be a case of failing to achieve the desired performance of the resulting electronic element.

In view of the above, an object of the present invention is to provide a novel hetero ring-containing siloxane polymer, a composition and an electronic material composition containing the polymer, and an electronic element, which do not cause a decrease in luminous efficiency and driving stability of an electronic element, by adding the polymer to an electronic material composition or ink to be used for coating film formation.

### Solution to Problem

As a result of an extensive research to solve the above objects, the inventors of the present invention have found that the electronic element produced from a composition or an electronic material composition containing a polymer which includes a novel hetero ring-containing siloxane polymer according to the present invention exhibits improved luminous efficiency and driving stability, thereby completing the present invention.

That is, the present invention is related to a novel monomer, a polymer thereof, a composition and an electronic material composition containing the polymer, and an electronic element containing the electronic material composition.

A copolymer obtained by copolymerizing a monomer represented by General Formula (1), and at least a monomer represented by General Formula (3) or General Formula (4).

[Chem.1]

A₁-L₁-B₁ (1)

(In General Formula (1), A₁ is a polymerizable reaction group, L₁ is a single bond, or a substituted or unsubstituted aromatic hydrocarbon or condensed aromatic hydrocarbon group each having 6 to 30 carbon atoms, and B₁ is represented by General Formula (2).)

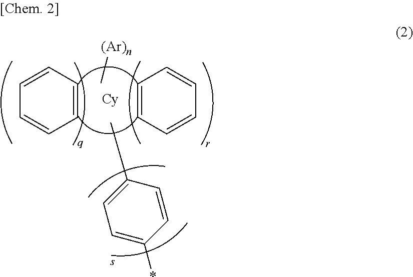

(In General Formula (2), a Cy ring represents a 5-membered or 6-membered aromatic ring which contains 1 to 3 nitrogen atoms and 0 to 1 oxygen atom. q, r, and s each independently represent 0 or 1, n is an integer of 0 to 2, Ar is a phenyl group or a biphenyl group, which each may have an alkyl group having 1 to 8 carbon atoms as a substituent, and * represents a linking to L₁ in General Formula (1).)

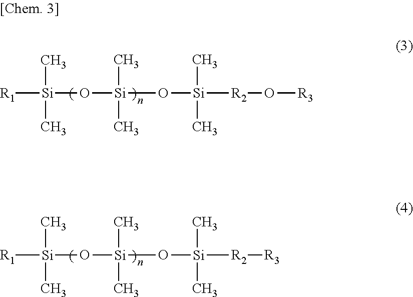

(In General Formulas (3) and (4), n represents 1 to 1,000, R₁ and R₂ represent a hydrocarbon group that may include an ether bonding, and R₃ represents a vinyl group or an organic group having a vinyl group.)

The copolymer in which the Cy ring in General Formula (2) is at least one selected from General Formulas (5) to (7).

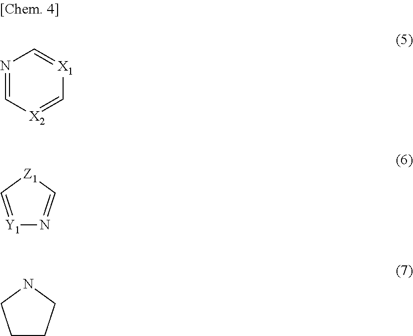

(In General'Formulas (5), (6), and (7), X₁, X₂, and X₃ each independently represent a carbon atom or a nitrogen atom. Y₁ is a carbon atom or a nitrogen atom. Z₁ is a nitrogen atom or an oxygen atom.)

A composition containing the polymer.

An electronic material composition containing the polymer.

An electronic element containing the composition or the electronic material composition.

### Advantageous Effects of Invention

According to the present invention, it has been found that a smooth organic thin film can be produced using the composition containing the novel hetero ring-containing siloxane polymer of the present invention, and that the electronic element obtained from the organic thin films exhibits improved luminous efficiency and driving stability.

### DESCRIPTION OF EMBODIMENTS

Embodiments of the present invention will be described in detail below.

[Hetero Ring-Containing Siloxane Polymer]

A hetero ring-containing siloxane polymer according to the present embodiment is a copolymer obtained by copolymerizing at least one hetero ring-containing monomer represented by General Formula (1) and a siloxane monomer. The hetero ring-containing siloxane polymer may be a copolymer obtained by copolymerizing at least one hetero ring-containing monomer represented by General Formula (1), a siloxane monomer, and a monomer other than the monomer represented by General Formula (1). This hetero ring-containing siloxane polymer may contain a component derived from a polymerization initiator or the like. In the present specification, the term “siloxane” means the “—Si—O—Si—” structure (siloxane structure).

In the incident, the siloxane monomer and the other monomers including the heterocyclic monomer, in the hetero ring-containing siloxane polymer, is preferably adjusted in view of the leveling performances of the hetero ring-containing siloxane polymer according to the present invention.

More Specifically, the silicon content in the hetero ring-containing siloxane polymer is preferably 0.1 mass % or more, more preferably 0.1 to 80.0 mass %, even more preferably 3 to 80 mass %, and still more preferably 5 to 80 mass %. The silicon content in the hetero ring-containing siloxane polymer is preferably 0.1 mass % or more from the viewpoint of a surface energy decrease. In this case, the silicon content can be controlled by adjusting the synthesis condition of the polymer, for example, the add amount of the siloxane monomer, as appropriate. Note that, the “silicon content” employed in the present specification is calculated from the following formula.

$$Silicon content ( mass \% ) = \frac{\begin{matrix}Atomic weight of \\ Silicon \times \\ Number of Silicon \\ Atoms in a \\ molecule\end{matrix}}{\begin{matrix}Molecular Weight \\ of Leveling Agent\end{matrix}} \times 100 \qquad [ Math . 1 ]$$

In a case where the hetero ring-containing siloxane polymer is used for forming a light emitting layer of an ink for an organic light emitting element, the heterocyclic monomer content in the hetero ring-containing siloxane polymer is preferably 0.1 mol % or more, more preferably 0.1 to 99 mol %, and even more preferably 1 to 99 mol % in view of charge injectability into a light-emitting layer. The heterocyclic monomer content in the hetero ring-containing siloxane polymer is preferably 0.1 mol % or more in view of improvement in charge injection into a light emitting layer. In this case, the heterocyclic monomer content can be controlled by adjusting the add amount of the hetero ring monomer as appropriate.

The weight-average molecular weight (Mw) of the hetero ring-containing siloxane polymer is preferably 500 to 100,000, and more preferably 3,000 to 40,000. In a case where the weight-average molecular weight (Mw) of the hetero ring-containing siloxane polymer is in the above range, unevenness of film thickness can be reduced, and in particular, in a case where the hetero ring-containing siloxane polymer used for forming an electronic material composition, the weight-average molecular weight (Mw) is preferably in the above range from the viewpoint of enabling homogeneous dissolution and dispersion of electronic material. Note that, the “weight-average molecular weight (Mw)” employed in the present specification is measured from the measurement methods described in Examples.

The number-average molecular weight (Mn) of the hetero ring-containing siloxane polymer is preferably 500 to 100,000, and more preferably 3,000 to 40,000. In a case where the number-average molecular weight (Mn) of the hetero ring-containing siloxane polymer is in the above range, unevenness of film thickness can be reduced, and in particular, in a case where the hetero ring-containing siloxane polymer used for forming an electronic material composition, the number-average molecular weight (Mn) is preferably in the above range from the viewpoint of enabling homogeneous dissolution and dispersion of electronic material. Note that, the “number-average molecular weight (Mn)” employed in the present specification is measured from the measurement methods described in Examples.

(Hetero Ring-Containing Monomer)

The hetero ring-containing monomer is represented by General Formula (1).

The copolymer is obtained by copolymerizing a monomer represented by General Formula (1), and at least a monomer represented by General Formula (3) or General Formula (4).

[Chem.5]

A₁-L₁-B₁ (1)

(In General Formula (1), A₁ is a polymerizable reaction group, L₁ is a sing bond or a substituted or unsubstituted aromatic hydrocarbon group or condensed aromatic hydrocarbon group having 6 to 30 carbon atoms, and B₁ is represented by General Formula (2).)

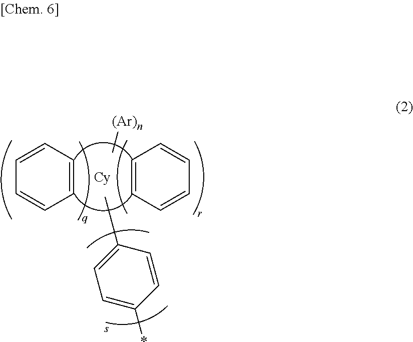

(In General Formula (2), a Cy ring represents a 5-membered aromatic ring or 6-membered aromatic ring which contains 1 to 3 nitrogen atoms and 0 to 1 oxygen atom. q, r, and s each independently represent 0 or 1, n is an integer of 0 to 2, Ar is a phenyl group or a biphenyl group, which each may have an alkyl group having 1 to 8 carbon atoms as a substituent, and * represents a linking to L₁ in General Formula (1).)

In General Formula (1), A₁ is preferably a methacryloxy group, an acryloxy group, a vinyl group, a vinyl group, or an organic group having a vinyl group, and more preferably a methacryloxy group, a vinyl group, or an organic group having a vinyl group.

Examples of the organic group having a vinyl group include aliphatic hydrocarbon groups having a vinyl group such as an allyl group, a 2-butenyl group, a 3-butenyl group, a 3-pentenyl group, a 4-pentenyl group, a 5-hexenyl group, a butadienyl group, a 2,4-pentadienyl group, a 3,5-hexadienyl group, a 4,6-heptadienyl group, and a 5,7-octadienyl group; vinyloxyalkylene groups such as a vinyl oxymethylene group, a vinyloxyethylene group, a vinyloxypropylene group, and a vinyloxybutylene group; a styryl group; aralkyl groups having a vinyl group such as a styrylmethylene group, a styrylethylene group, a styrylpropylene group, and a styrylbutylene group; and styryloxyalkylene groups such as a styryloxymethylene group, a styryloxyethylene group, a styryloxypropylene group, and a styryloxybutylene group. Among those, preferred are aliphatic hydrocarbon groups having a vinyl group, a styryl group, and aralkyl groups having a vinyl group in view of excellent polymerizability, and particularly preferred are a vinyl group, a butadienyl group, a pentadienyl group, a styryl group, and aralkyl groups having a vinyl group in view of easy designability of polymers with various molecular weights.

Examples of the aromatic hydrocarbon or condensed aromatic hydrocarbon groups having 6 to 30 ring-forming carbons include a phenyl group, a naphthyl group, a phenanthryl group, a biphenyl group, a terphenyl group, a quarterphenyl group, a fluoranthenyl group, a triphenylenyl group, a phenanthrenyl group, a pyrenyl group, a chrysenyl group, a fluorenyl group, and a 9,9-dimethylfluorenyl group. Among those, preferred are aromatic hydrocarbon or condensed aromatic hydrocarbon groups having 6 to 20 ring-forming carbons.

Examples of the Cy ring include a pyrrolyl group, a pyrazinyl group, a pyridinyl group, an indolyl group, an isoindolyl group, a furyl group, benzofuranyl group, an isobenzofuranyl group, a dibenzofuranyl group, a dibenzothiophenyl group, a quinolyl group, an isoquinolyl group, a quinoxalinyl group, a carbazolyl group, a p henanthridinyl group, an acridinyl group, a phenanthrolinyl group, a thienyl group, and groups formed of rings such as a pyridine ring, a pyrazine ring, a pyrimidine ring, a pyridazine ring, a triazine ring, an indole ring, a quinoline ring, an acridine ring, a pyrrolidine ring, a dioxane ring, a piperidine ring, a morpholine ring, a piperazine ring, a carbazole ring, a furan ring, a thiophene ring, an oxazole ring, an oxadiazole ring, a benzoxazole ring, a thiazole ring, a thiadiazole ring, a benzothiazole ring, a triazole ring, an imidazole ring, a benzimidazole ring, a pyran ring, and a dibenzofuran ring. Among those, preferred are a pyridine ring, a pyrimidine ring, a triazine ring, carbazole ring, an oxadiazole ring, a triazole ring, an imidazole ring and a benzimidazole ring.

Specific examples of the hetero ring-containing monomer represented by General Formula (1) include the following compounds.

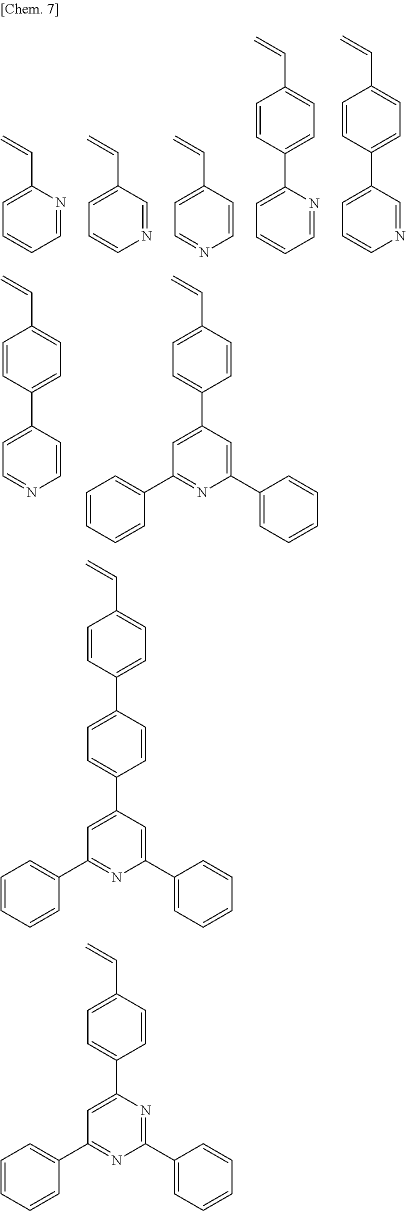

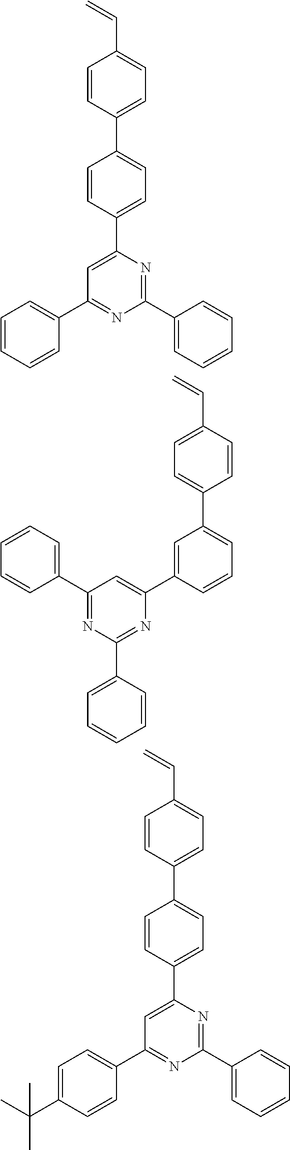

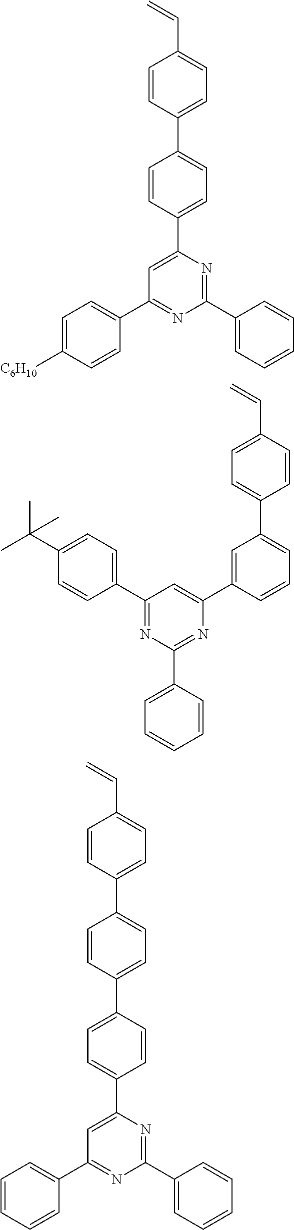

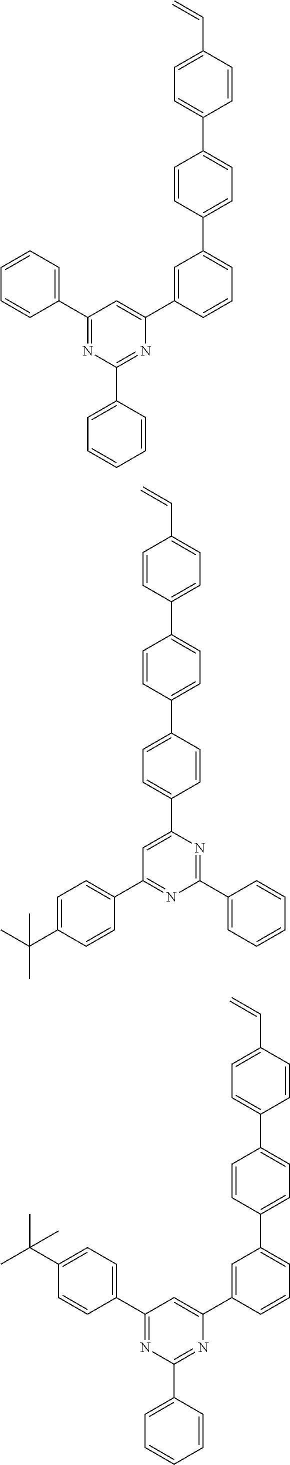

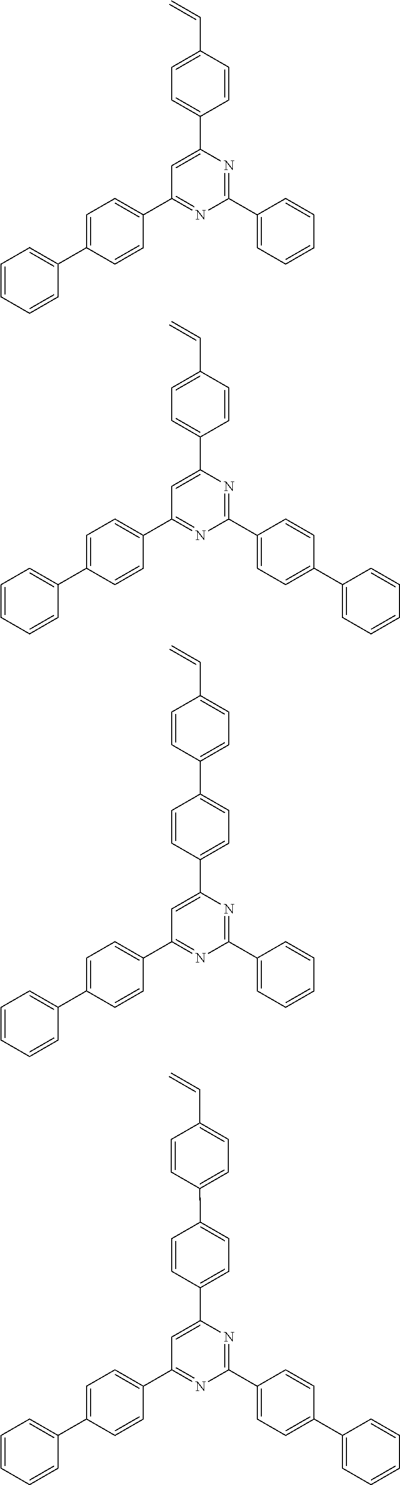

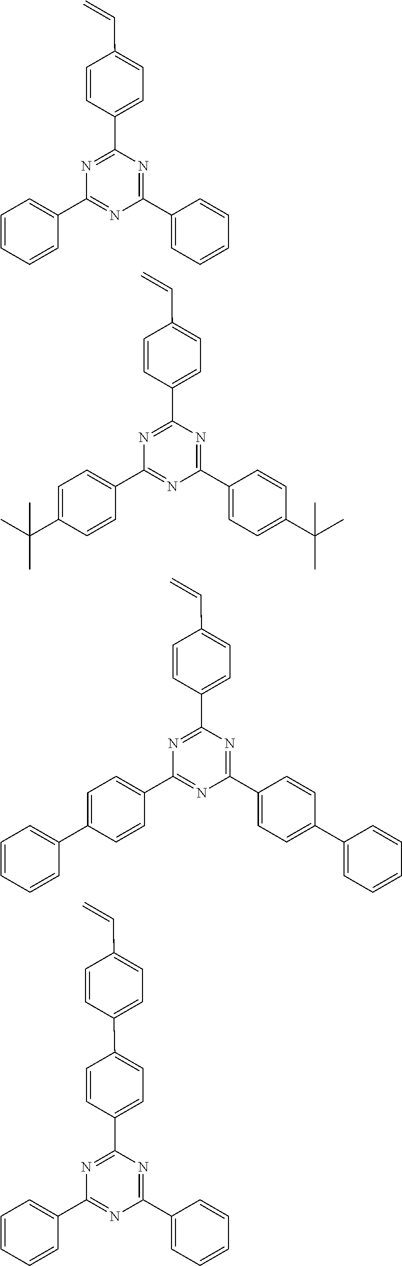

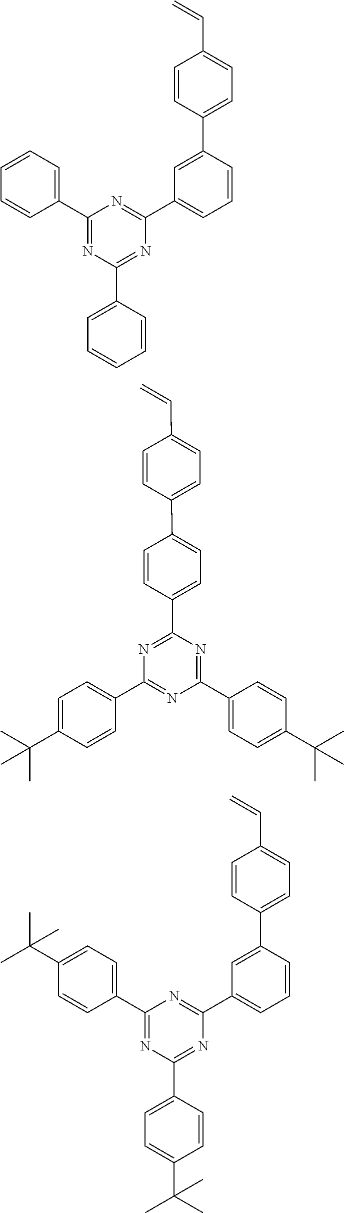

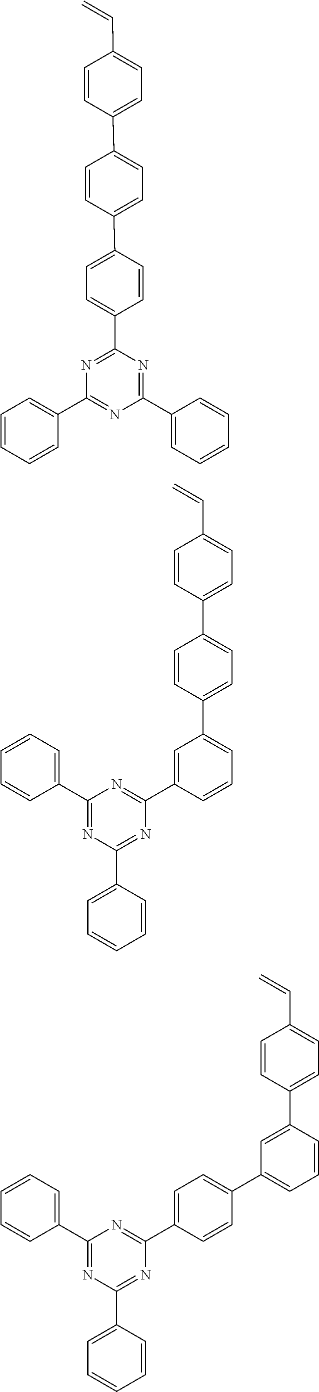

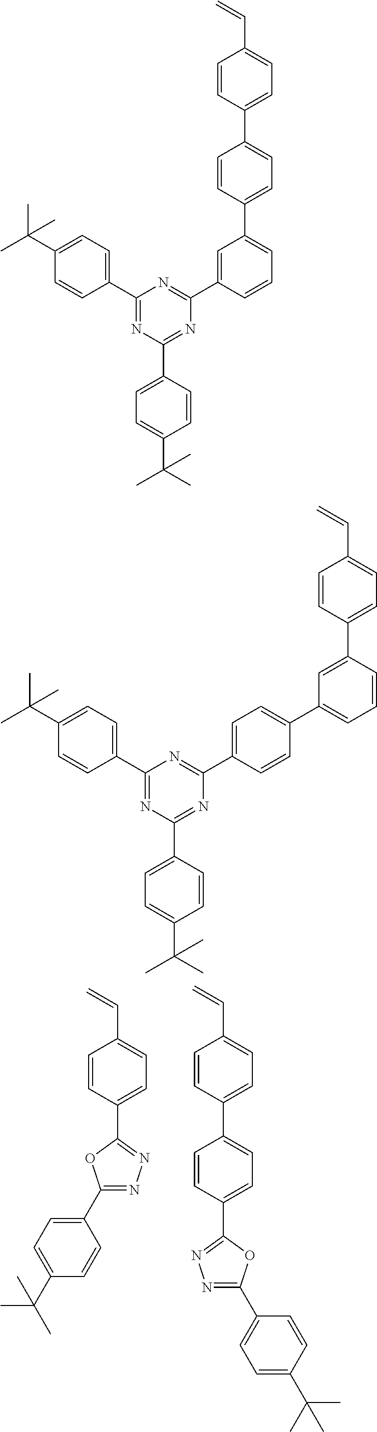

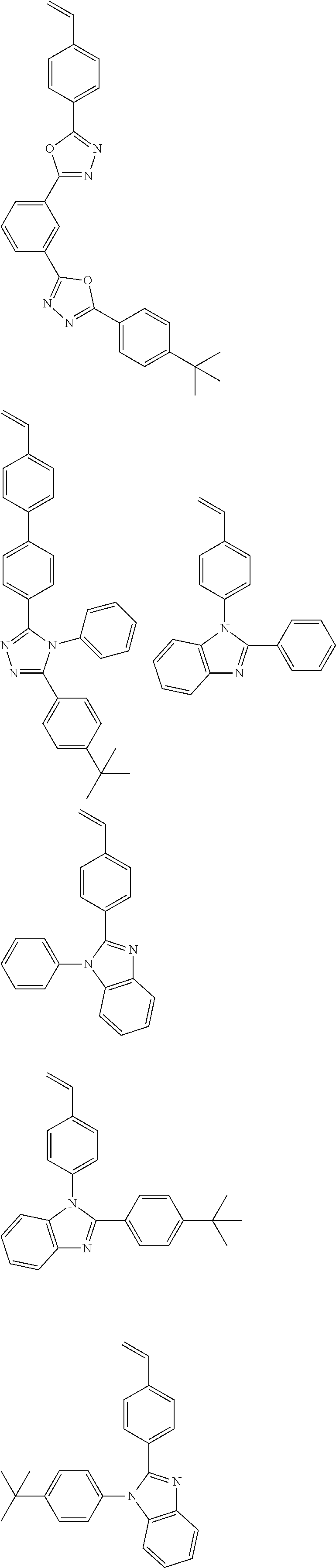

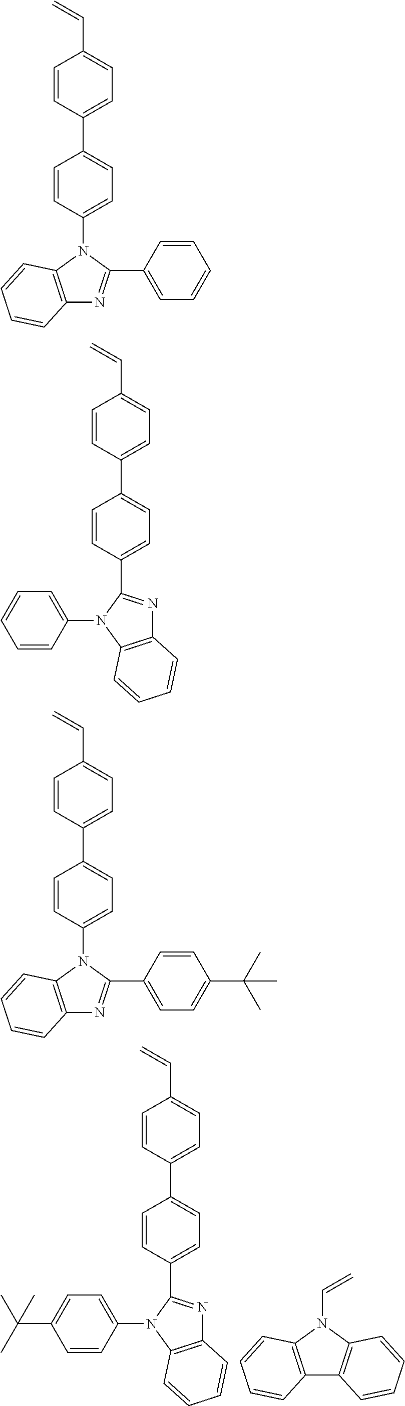

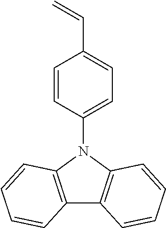

(Siloxane Monomer)

Although there is no particular limitation on the siloxane group included in the siloxane monomer, the siloxane group is preferably one represented by the following formula (3) or formula (4).

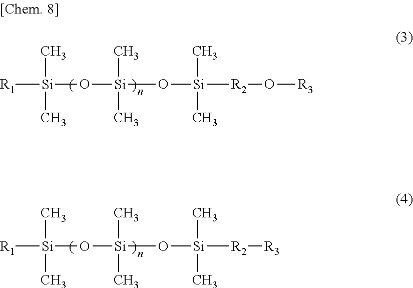

(In General Formula (3) and General Formula (4), n represents 1 to 1,000, R₁ and R₂ represent a hydrocarbon group that may include an ether bonding. R₃ represents a methacryloxy group, an acryloxy group, a vinyl group, or an organic group having a vinyl group.)

There is no particular limitation on R₁; examples thereof include a C1 to C10 alkyl group, a C2 to C10 alkoxyalkyl group, a C3 to C30 cycloalkyl group, a C4 to C30 cycloalkoxyalkyl group, a C6 to C20 aryl group, and a C6 to C20 aryloxy group.

There is no particular limitation on the C1 to C10 alkyl group; examples thereof include a methyl group, an ethyl group, a propyl group, an isopropyl group, a butyl group, an iso-butyl group, a sec-butyl group, a tert-butyl group, a pentyl group, a hexyl group, and a decyl group.

There is no particular limitation on the C2 to C10 alkoxyalkyl group; examples thereof include a methoxymethyl group, a methoxyethyl group, an ethoxyethyl group, a propoxyethyl group, a propoxypropyl group, a butoxypropyl group, a butoxybutyl group, a butoxypentyl group, and a pentyloxypentyl group.

There is no particular limitation on the C3 to C30 cycloalkyl group; examples thereof include a cyclopropyl group, a cyclobutyl group, a cyclopentyl group, a cyclohexyl group, a cycloheptyl group, a tricyclo [5,2,1,0 (2,6) ]decyl group, and an adamantyl group, and the cycloalkyl group preferably includes 3 to 18 carbon atoms.

There is no particular limitation on the C4 to C30 cycloalkoxyalkyl group; examples thereof include a cyclopropyloxymethyl group, a cyclobutyloxyethyl group, a cyclopentyloxypropyl group, a cyclohexyloxypropyl group, a cycloheptyloxypropyl group, a tricyclo [5,2,1,0(2,6)]decyloxypropyl group, and an adamantyloxypropyl group, and the cycloalkoxyalkyl group preferably includes 3 to 18 carbon atoms.

Examples of the C6 to C20 aryl group include a phenyl group, a naphthyl group, an anthracenyl group, and a biphenyl group.

Examples of the C6 to C20 aryloxy group include a phenyloxy group, a naphthyloxy group, an anthracenyloxy group, and a biphenyloxy group.

In this case, at least one of hydrogen atoms that constitute the C1 to C10 alkyl group, the C1 to C10 alkoxyalkyl group, the C3 to C30 cycloalkyl group, the C3 to C30 cycloalkoxyalkyl group, the C6 to C20 aryl group, or the C6 to C20 aryloxy group may be substituted with the C1 to C10 alkyl group.

Among them, R₁ is preferably the C1 to C10 alkyl group from the viewpoint of enhancing the leveling property, more preferably a methyl group, an ethyl group, a propyl group, an isopropyl group, a butyl group, an iso-butyl group, a sec-butyl group, or a tert-butyl group from the viewpoint of increasing compatibility with a solvent, and even more preferably a methyl group, an ethyl group, a propyl group, or a butyl group from the viewpoint of improving the electronic element characteristics.

There is no particular limitation on R₂; examples thereof include a C1 to C10 alkylene group, a C2 to C10 alkyleneoxyalkylene group, a C3 to C30 cycloalkylene group, a C4 to C30 cycloalkyleneoxyalkylene group, a C6 to C20 arylene group, and a C7 to C20 aryleneoxyalkylene group.

There is no particular limitation on the C1 to C10 alkylene group; examples thereof include a methylene group, an ethylene group, a propylene group, an isopropylene group, a butylene group, an iso-butylene group, a pentylene group, a hexylene group, and a decylene group.

There is no particular limitation on the C2 to C10 alkyleneoxyalkylene group; examples thereof include a methyleneoxymethylene group, an ethyleneoxymethylene group, an ethyleneoxypropylene group, a propyleneoxyethylene group, a propyleneoxypropylene group, a propyleneoxybutylene group, a butyleneoxybutylene group, a butyleneoxypentylene group, and a pentyleneoxypentylene group.

There is no particular limitation on the C3 to C30 cycloalkylene group; examples thereof include a cyclopropylene group, a cyclobutylene group, a cyclopentylene group, a cyclohexylene group, and a cycloheptylene group, and the cycloalkylene group preferably includes 3 to 10 carbon atoms.

There is no particular limitation on the C4 to C30 cycloalkyleneoxyalkyl group; examples thereof include a cyclopropyleneoxyethylene group, a cyclobutyleneoxypropylene group, a cyclopentyleneoxypropylene group, a cyclohexyleneoxypropylene group, and a cycloheptylene oxypropylene group, and the cycloalkyleneoxyalkyl group preferably includes 3 to 10 carbon atoms.

Examples of the C6 to C20 arylene group include a phenylene group, a naphthylene group, an anthracenylene group, and a biphenylene group.

Examples of the C7 to C20 aryleneoxyalkylene group include a phenyleneoxypropylene group, a naphthyleneoxypropylene group, an anthracenyleneoxypropylene group, and a biphenyleneoxypropylene group.

In this case, at least one of hydrogen atoms that constitute the C1 to C10 alkylene group, the C2 to C10 alkyleneoxyalkylene group, the C3 to C30 cycloalkylene group, the C4 to C30 cycloalkyleneoxyalkylene group, the C6 to C20 arylene group, and the C7 to C20 aryleneoxyalkylene group may be substituted with the above-mentioned C1 to C10 alkyl group.

Among them, R₂ is preferably the C1 to C10 alkylene group or the C2 to C10 alkyleneoxyalkylene group from the viewpoint of enhancing the leveling property, more preferably a methylene group, an ethylene group, a propylene group, an isopropylene group, a butylene group, an isobutylene group, a pentylene group, a hexylene group, a methyleneoxymethylene group, methyleneoxyethylene group, an ethyleneoxyethylene group, ethyleneoxypropylene group, a propyleneoxyethylene group, a propyleneoxypropylene group, a propyleneoxybutylene group, or a butyleneoxybutylene group from the viewpoint of enhancing solubility, and even more preferably an ethylene group, a propylene group, a butylene group, an ethyleneoxyethylene group, an ethyleneoxypropylene group, a propyleneoxyethylene group, or a propyleneoxypropylene group from the viewpoint of improving the electronic element characteristics.

R₃ is a methacryloxy group, an acryloxy group, a vinyl group, or an organic group including a vinyl group.

Examples of the organic group including a vinyl group include aliphatic hydrocarbon groups including a vinyl group such as an allyl group, a 2-butenyl group, a 3-butenyl group, a 3-pentenyl group, a 4-pentenyl group, a 5-hexenyl group, a butadienyl group, a 2,4-pentadienyl group, a 3,5-hexadienyl group, a 4,6-heptadienyl group, and a 5,7-octadienyl group; vinyloxyalkylene groups such as a vinyloxymethylene group, a vinyloxyethylene group, a vinyloxypropylene group, and a vinyloxybutylene group; styryl group; aralkyl groups including a vinyl group such as a styryl methylene group, a styryl ethylene group, a styryl propylene group, and a styrylbutylene group; and styryloxyalkylene groups such as a styryloxymethylene group, a styryloxyethylene group, a styryloxypropylene group, and a styryloxybutylene group.

Among them, from the viewpoint of excellent polymerizability, a methacryloxy group, a vinyl group, an aliphatic hydrocarbon group including a vinyl group, a styryl group, and an aralkyl group including a vinyl group are preferred, and from the viewpoint of easy designability of polymers of various molecular weights, a methacryloxy group, a vinyl group, a butadienyl group, a pentadienyl group, a styryl group, and an aralkyl group including a vinyl group are more preferred, and from the viewpoint that the resulting polymer improves the driving stability of the electronic element, a vinyl group, a butadienyl group, a 2,4-pentadienyl group, a styryl group, and a styrylmethylene group are even more preferred.

In the general formula, n is 1 to 1,000, preferably 3 to 500 from the viewpoint of allowing the coating film obtained from the electronic material composition or ink to exhibit excellent smoothness, and more preferably 5 to 200 from the viewpoint of improving driving stability of the electronic element.

Specific examples of the siloxane monomers are shown below, but are not limited thereto.

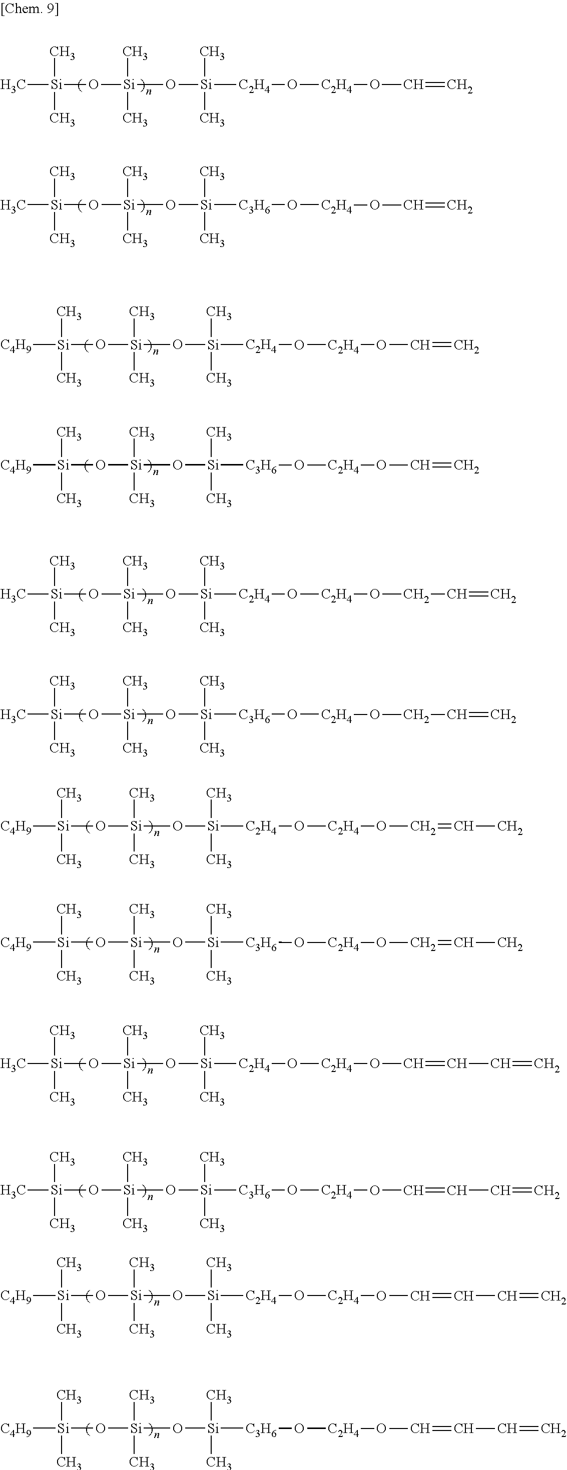

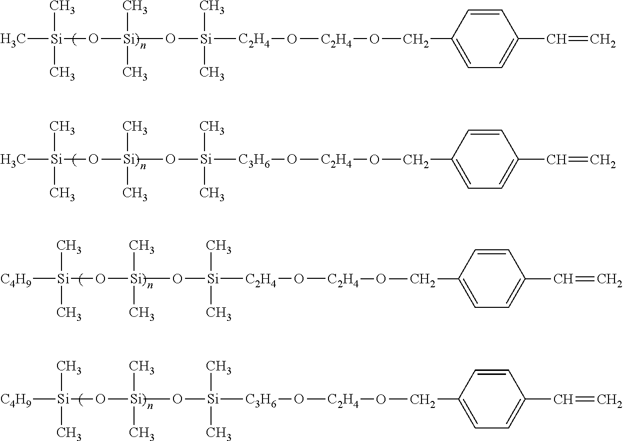

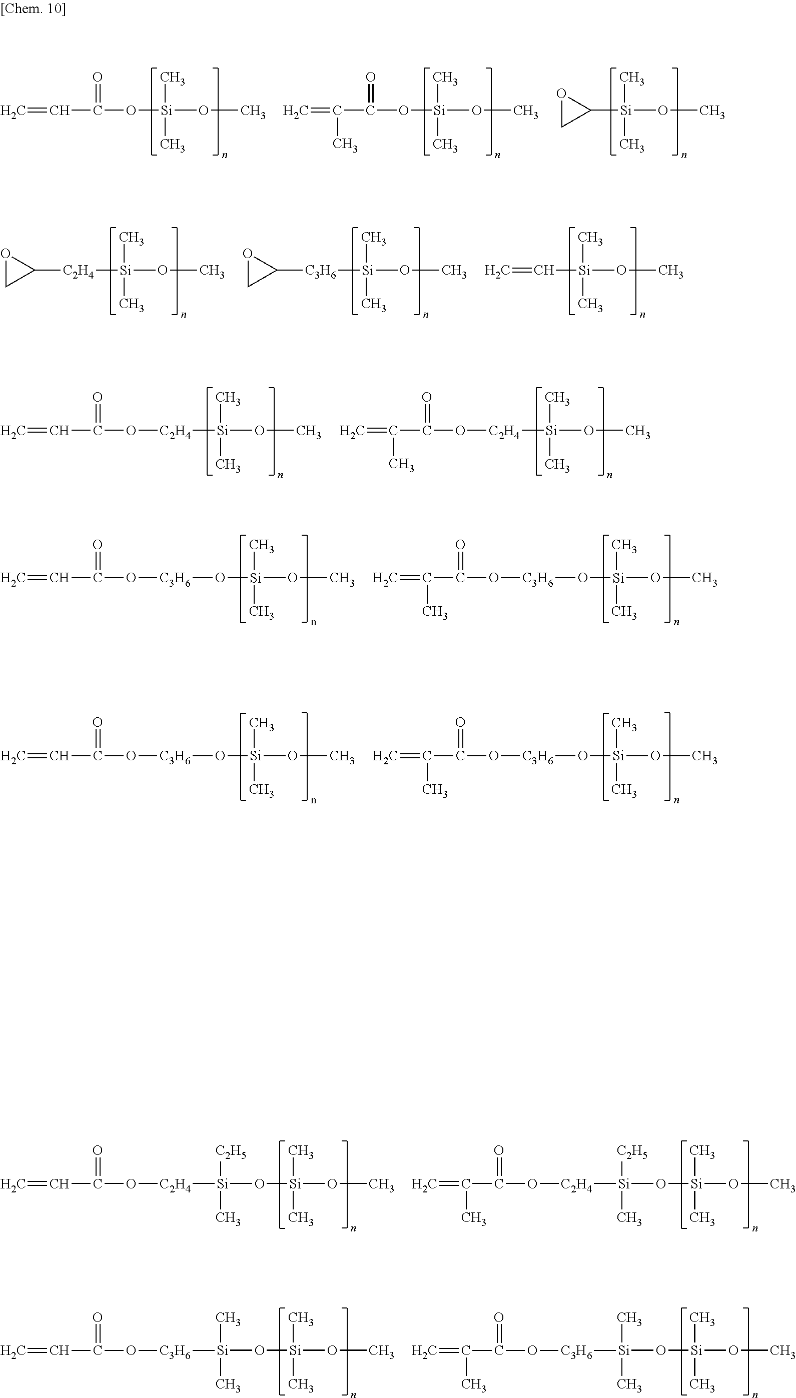

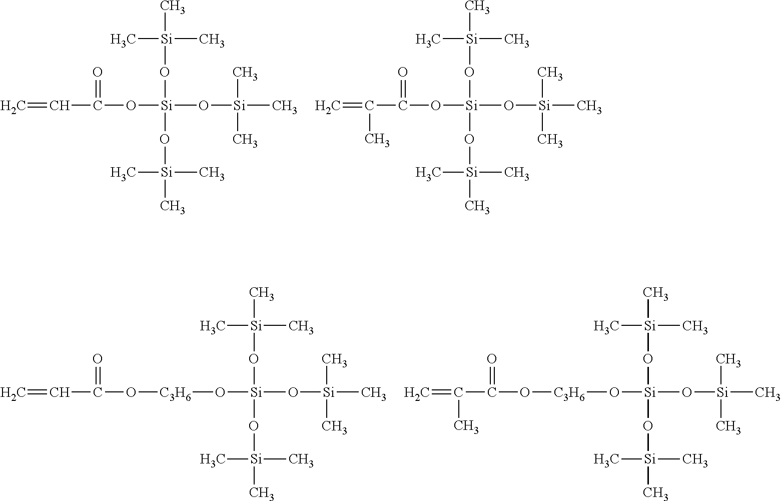

(In the above chemical formulae, n is an integer of 1 to 1,000.) (Monomers Other than the Monomers Represented by the General Formula (1))

There is no particular limitation on the monomer other than the monomers represented by the general formula (1), for example, and commonly known (meth)acrylate monomers, styryl monomers, vinyl ether monomers, and allyl monomers and the like may be used.

There is no particular limitation on the (meth)acrylate monomers; examples thereof include alkyl (meth) acrylate esters such as methyl (meth)acrylate, ethyl (meth)acrylate, propyl (meth)acrylate, n-butyl (meth)acrylate, t-butyl (meth)acrylate, hexyl (meth)acrylate, heptyl (meth)acrylate, octyl (meth)acrylate, nonyl (meth)acrylate, decyl (meth)acrylate, dodecyl (meth)acrylate, tetradecyl (meth) acrylate, hexadecyl (meth) acrylate, octadecyl (meth)acrylate, and docosyl (meth)acrylate; cycloalkyl (meth)acrylate esters such as cyclohexyl(meth)acrylate, isobornyl (meth) acrylate, dicyclopentanyl (meth) acrylate, and dicyclopentanyloxyethyl (meth)acrylate; aryl (meth) acrylate esters such as benzoyloxyethyl (meth) acrylate, benzyl (meth)acrylate, phenylethyl (meth)acrylate, phenoxyethyl (meth)acrylate, phenoxydiethyl glycol (meth) acrylate, and 2-hydroxy-3-phenoxypropyl (meth) acrylate.

There is no particular limitation on the styryl monomers, and examples thereof include styrene and styrene derivatives such as alkyl-substitutedstyrene, e.g., α-methylstyrene, α-ethylstyrene, α-butylstyrene, and 4-methylstyrene, and chlorostyrene.

There is no particular limitation on the vinyl ether monomer; examples thereof include alkyl vinyl ethers such as methyl vinyl ether, ethyl vinyl ether, propyl vinyl ether, isopropyl vinyl ether, n-butyl vinyl ether, sec-butyl vinyl ether, tert-butyl vinyl ether, isobutyl vinyl ether, n-amyl vinyl ether, and isoamyl vinyl ether; cycloalkyl vinyl ethers such as cyclopentyl vinyl ether, cyclohexyl vinyl ether, cycloheptyl vinyl ether, cyclooctyl vinyl ether, 2-bicyclo[2.2.1]heptyl vinyl ether, 2-bicyclo[2.2.2]octyl vinyl ether, 8-tricyclo[5.2.1.0(2,6)]decanyl vinyl ether, 1-adamantyl vinyl ether, and 2-adamantyl vinyl ether; aryl vinyl ethers such as phenyl vinyl ether, 4-methylphenyl vinyl ether, 4-trifluoromethylphenyl vinyl ether, and 4-fluorophenyl vinyl ether; and aryl vinyl ethers such as benzyl vinyl ether, and 4-fluorobenzyl vinyl ether.

There is no particular limitation on the allyl monomers; examples thereof include alkyl allyl ethers such as methyl allyl ether, ethyl allyl ether, propyl allyl ether, and butyl allyl ether; and aryl allyl ethers such as phenyl allyl ether; allyl acetate, allyl alcohol, and allylamine.

In particular, these (meth) acrylate monomers, the styryl monomers, the vinyl ether monomers, and the allylic monomers preferably include a hydrophobic group. In the present specification, the term “hydrophobic group” refers to a group, where the solubility in water (25° C., 25% RH) of a molecule formed by bonding a hydrophobic group to a hydrogen atom is 100 mg/L or less.

There is no particular limitation on the hydrophobic group; examples thereof include a C1 to C18 alkyl group, a C3 to C20 cycloalkyl group, and a C6 to C 30 aryl group.

There is no particular limitation on the C1 to C18 alkyl group; examples thereof include methyl group, ethyl group, propyl group, isopropyl group, butyl group, iso-butyl group, sec-butyl group, tert-butyl group, pentyl group, hexyl group, decyl group, undecyl group, dodecyl group, octadecyl group, and 2-ethylhexyl group.

There is no particular limitation on the C3 to C20 cycloalkyl group; examples thereof include a cyclopropyl group, a cyclobutyl group, a cyclopentyl group, a cyclohexyl group, a cycloheptyl group, tricyclo [5,2,1,0(2,6)]decyl group, and adamantyl group.

Examples of the C6 to C30 aryl group include phenyl, naphthyl, anthracenyl, and biphenyl.

Examples of monomers including such a hydrophobic group include alkyl (meth) acrylate esters, cycloalkyl (meth) acrylate esters, aryl (meth)acrylate esters, styrene, alkyl-substituted styrenes, alkyl vinyl ethers, cycloalkyl vinyl ethers, aryl vinyl ethers, alkyl allyl ethers, and aryl allyl ethers.

Among the monomers including a hydrophobic group, from the viewpoint of satisfactory copolymerizability to the monomers represented by the general formula (1) and obtaining polymers with various molecular weights, preferable examples include the alkyl (meth) acrylate esters, cycloalkyl (meth) acrylate esters, aryl (meth)acrylate esters, styrene, alkyl-substituted styrenes, alkyl vinyl ethers, cycloalkyl vinyl ethers, and aryl vinyl ethers. From the viewpoint that the resulting polymer more favorably exhibits the leveling property improving effect, it is preferable to use an aromatic compound-containing monomer including aryl groups such as aryl (meth) acrylate esters, styrene, alkyl-substituted styrenes, and aryl vinyl ethers, and from the viewpoint of driving stability of the electronic element, styrene, alkyl-substituted styrenes, and aryl vinyl ether are more preferable, and when styrene, alkyl-substituted styrenes, phenyl vinyl ether, or benzyl vinyl ether is employed, the effect of the present invention is particularly remarkable.

The above-mentioned monomers may be used singly, or two or more thereof may be used in combination.

The weight-average molecular weight (Mw) of the polymer of the present invention is preferably 500 to 100,000, and more preferably 3,000 to 40,000 from the viewpoint of smoothness. Note that, in the present specification, the value of “weight-average molecular weight (Mw)” refers to a value obtained according to the measurement method shown in Examples.

The number-average molecular weight (Mn) of the polymer of the present invention is preferably 500 to 100,000, and more preferably 3,000 to 40,000 from the viewpoint of smoothness. Furthermore, in the present specification, the value of “number-average molecular weight (Mn) refers to a value obtained according to the measurement method shown in Examples.

[Method of Preparing Polymer]

The polymer of the present invention may be obtained through any commonly known method for polymerization (copolymerization) using the above-mentioned monomers and polymerization initiator, and the polymer may be any of a random copolymer, a block copolymer, and a graft copolymer.

Examples of the polymerization method include radical polymerization, anionic polymerization, and cationic polymerization.

The radical polymerization is not carried out under particularly limited reaction condition; the radical polymerization may be carried out in a solvent using a monomer and radical polymerization initiator, for example.

Any commonly known radical polymerization initiators may be used; examples thereof include azo compounds such as 2,2′-azobisisobutyronitrile, 2,2′-azobis-(2,4-dimethylvaleronitrile), and 2,2′-azobis-(4-methoxy-2,4-dimethylvaleronitrile); and organic peroxides such as benzoyl peroxide, lauroyl peroxide, t-butyl peroxypivalate, t-butyl peroxyethyl hexanoate, 1,1′-bis-(t-butylperoxy) cyclohexane, t-amylperoxy-2-ethylhexanoate, and t-hexylperoxy-2-ethylhexanoate and hydrogen peroxides. These may be used singly, and two or more thereof may be used in combination.

There is no particular limitation on the use amount of the radical polymerization initiator; the use amount is typically 0.001 parts to 1 part by mass with respect to 100 parts by mass of the monomer. In obtaining the polymer of the present invention within the range of the above-mentioned preferable weight-average molecular weight, the use amount of the radical polymerization initiator is preferably 0.005 to 0.5 parts by mass, and more preferably 0.01 to 0.3 parts by mass, with respect to 100 parts by mass of the monomer.

Representative examples of the solvent that may be used for the radical polymerization include ketone solvents such as acetone, methyl ethyl ketone, methyl-n-propyl ketone, methyl isopropyl ketone, methyl-n-butyl ketone, methyl isobutyl ketone, methyl-n-amyl ketone, methyl-n-hexyl ketone, diethyl ketone, ethyl-n-butyl ketone, di-n-propyl ketone, diisobutyl ketone, cyclohexanone, and holon;

ether solvents such as ethyl ether, isopropyl ether, n-butyl ether, diisoamyl ether, ethylene glycol dimethyl ether, ethylene glycol diethyl ether, diethylene glycol dimethyl ether, diethylene glycol, dioxane, and tetrahydrofuran;

ester solvents such as ethyl formate, propyl formate, n-butyl formate, ethyl acetate, n-propyl acetate, isopropyl acetate, n-butyl acetate, n-amyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and ethyl-3-ethoxypropionate;

alcoholic solvents such as methanol, ethanol, isopropyl alcohol, n-butyl alcohol, isobutyl alcohol, diacetone alcohol, 3-methoxy-1-propanol, 3-methoxy-1-butanol, and 3-methyl-3-methoxybutanol; and hydrocarbon solvents such as toluene, xylene, Solvesso 100, Solvesso 150, Swazole 1800, Swazole 310, Isopar E, Isopar G, Exxon Naphtha no. 5, and Exxon Naphtha no. 6.

These solvents may be used singly, and two or more thereof may be used in combination.

There is no particular limitation on the use amount of the solvent in the radical polymerization reaction; and the use amount is preferably 0 parts to 3,000 parts by mass from the viewpoint of stirring property more preferably 10 parts to 1,000 parts by mass from the viewpoint of reactivity, and even more preferably 10 parts to 500 parts by mass from the viewpoint of molecular weight controllability, with respect to 100 parts by mass of the charged amount of the monomer.

The reaction condition for the anionic polymerization is not limited particularly, and the anionic polymerization maybe carried out in a solvent using a monomer and an anionic polymerization initiator, for example.

Any commonly known anionic polymerization initiator may be used; examples thereof include organic alkali metals such as methyl lithium, n-butyl lithium, sec-butyl lithium, t-butyl lithium, isopropyl lithium, n-propyl lithium, isopropyl lithium, phenyl lithium, benzyl lithium, hexyl lithium, butyl sodium, and butyl potassium; organic alkaline earth metals such as methyl magnesium chloride, methyl magnesium bromide, methyl magnesium iodide, ethyl magnesium bromide, propyl magnesium bromide, phenyl magnesium chloride, phenyl magnesium bromide, and dibutyl magnesium; alkali metals such as lithium, sodium, and potassium; organic zinc such as diethyl zinc, dibutyl zinc, and ethyl butyl zinc; and organic aluminum such as trimethyl aluminum, triethyl aluminum, methyl bisphenoxy aluminum, isopropyl bisphenoxy aluminum, bis(2,6-di-t-butylphenoxy)methyl aluminum, and bis(2,6-di-t-butyl-4-methylphenoxy)methyl aluminum. These initiators may be used singly or two or more thereof may be used in combination.

There is no particular limitation on the use amount of the anionic polymerization initiator to be used; the use amount is preferably 0.001 parts to 1 part by mass, more preferably 0.005 parts to 0.5 parts by mass, and even more preferably 0.01 parts to 0.3 parts by mass, with respect to 100 parts by mass of the monomer.

The examples of the solvent that may be used for the anionic polymerization include the above-mentioned solvents.

There is no particular limitation on the use amount of the solvent used in the anionic polymerization reaction; the use amount is preferably 0 parts to 3,000 parts by mass from the viewpoint of stirring property, more preferably 10 parts to 1,000 parts by mass from the viewpoint of reactivity, and even more preferably 10 parts to 500 parts by mass from the viewpoint of molecular weight controllability, with respect to 100 parts by mass of the charged amount of the monomer.

The reaction condition for the cationic polymerization is not particularly limited, and the cationic polymerization may be carried out, for example, in a solvent using a monomer and a cationic polymerization initiator.

Any commonly known cationic polymerization initiator may be used; examples thereof include protonic acids such as hydrochloric acid, sulfuric acid, perchloric acid, trifluoroacetic acid, methanesulfonic acid, trifluoromethanesulfonic acid, chlorosulfonic acid, and fluorosulfonic acid; and lewis acids such as boron trifluoride, aluminum chloride, titanium tetrachloride, stannic chloride, and ferric chloride. These initiators maybe used singly, or two or more thereof may be used in combination.

There is no particular limitation on the use amount of the cationic polymerization initiator; the use amount is typically 0.001 parts to 1 part by mass, with respect to 100 parts by mass of the monomer. In obtaining the polymer of the present invention having a weight average molecular weight falling within the preferable range mentioned above, the use amount of the cationic polymerization initiator is preferably 0.005 parts to 0.5 parts by mass, and more preferably 0.01 parts to 0.3 parts by mass, with respect to 100 parts by mass of the monomer.

The examples of the solvent that may be used for the cationic polymerization include the solvents that maybe used for the above-mentioned radical polymerization.

There is no particular limitation on the use amount of the solvent in the cationic polymerization reaction; the use amount is preferably 0 parts to 3,000 parts by mass from the viewpoint of stirring property, more preferably 10 parts to 51,000 parts by mass from the viewpoint of reactivity, and even more preferably 10 parts to 500 parts by mass from the viewpoint of molecular weight controllability, with respect to 100 parts by mass of the charged amount of the monomer.

The radical polymerization, anionic polymerization, and cationic polymerization may be carried out in a form of living polymerization; methods described in “Quarterly Chemistry Review No.18, 1993, Precise polymerization edited by Chemical Society of Japan (Academic Press Center)” may be used, for example.

[Composition]

The composition containing the polymer of the present invention has a function of improving the leveling property after film formation, and thus may be used for curing compositions to be cured by heat or light, ink compositions, coating compositions, and electronic material compositions, but the application thereof is not limited thereto. Among them, the polymer of the present invention is useful for the electronic material compositions since the electric characteristics of the electronic element are not deteriorated.

[Electronic Material Composition]

The electronic material composition containing the polymer of the present invention includes an organic semiconductor material, the polymer (leveling agent) of the present invention, and a solvent. The electronic material composition may further include a surfactant or the like other than the above materials, as necessary.

The content of the organic semiconductor material is preferably 0.01% to 10% by mass, and more preferably 0.01% to 5% by mass from the viewpoint of electrical characteristics, with respect to the total amount of the electronic material composition.

The content of the polymer of the present invention is preferably 0.001% to 5.0% by mass, and more preferably 0.001% to 1.0% by mass from the viewpoint of leveling property, with respect to the total amount of the electronic material composition.

The content of the solvent is preferably 90% to 99% by mass, and more preferably 95% to 99% by mass from the viewpoint of film formability, with respect to the total amount of the electronic material composition.

(Organic Semiconductor Material)

Examples of the organic semiconductor material include organic TFT materials, organic solar cell materials, and organic EL materials, but are not limited thereto.

There is no particular limitation on the organic TFT material so long as the material can be used for a layer constituting the organic TFT element; examples thereof include acenes which may have a substituent such as naphthalene, anthracene, tetracene, pentacene, hexacene, and heptacene, e.g., compounds having a styryl structure represented by C₆H₅—CH═CH—C₆H₅ such as 1,4-bistyrylbenzene, 1,4-bis(2-methylstyryl)benzene, 1,4-bis (3-methylstyryl)benzene(4MSB), 1,4-bis(4-methylstyryl)benzene, and polyphenylene vinylene, oligomers and polymers of such compounds, thiophene oligomers which may have a substituent such as derivatives of α4T, α5T, α6T, α7T, and α8T, thiophene polymers such as polyhexylthiophene and poly(9,9-dioctylfluorenyl-2,7-diyl-co-bithiophene), condensed oligothiophenes, in particular, compounds having a thienobenzene skeleton or a dithienobenzene skeleton, such as bisbenzothiophene derivatives, α,α′-bis(dithieno [3,2-b: 2′,3′-d]thiophene), co-oligomer of dithienothiophene-thiophene, and pentathienoacene, [1]benzothieno[3,2-b] [1]benzothiophene derivatives, selenophene oligomers, porphyrins such as metal-free phthalocyanine, copper phthalocyanine, lead phthalocyanine, titanyl phthalocyanine, platinum porphyrin, porphyrin, and benzoporphyrin, tetrathiafulvalene(TTF) and derivatives thereof, rubrene and derivatives thereof, tetracyanoquinodimethane(TCNQ), quinoid oligomer of 11,11,12,12-tetracyano naphtho-2,6-quinodimethane(TCNNQ), fullerenes such as C60, C70, and PCBM, and tetracarboxylic acids such as N,N′-diphenyl-3,4,9,10-perylene tetracarboxylate diimide, N,N′-dioctyl-3,4,9,10-perylenetetracarboxylate diimide(C8-PTCDI), NTCDA, and 1,4,5,8-naphthalenetetracarboxylate diimide(NTCDI).

There is no particular limitation on the organic solar cell material so long as the material can be used for a layer constituting an organic solar cell element; examples thereof include fullerenes such as C60 and C70, fullerene derivatives, carbon nanotubes, perylene derivatives, polycyclic quinones, and quinacridone, and examples of polymers that can be further exemplified as the organic solar cell material include CN-poly(phenylene-vinylene), MEH—CN—PPV, polymers containing —CN group or —CF₃ group, —CF₃-substituted polymers thereof, and poly(fluorene) derivatives.

There is no particular limitation on the organic EL material so long as the material can be used for a layer constituting an organic EL element. In one embodiment, examples of the organic EL material that the electronic material composition may contain include light emitting materials used for a light emitting layer, hole injection materials used for a hole injection layer, hole transport materials used for a hole transport layer, and electron transport materials used for an electron transport layer.

(Light Emitting Material)

A light emitting material includes a host material and a dopant material.

While the composition ratio of the host material to the dopant material is not limited, the dopant is preferably 1 part to 50 parts by mass, and more preferably 5 parts to 20 parts by mass from the viewpoint of luminous efficiency, with respect to 100 parts by mass of the host.

The host material is classified into a high molecular weight host material and a low molecular weight host material. In the present specification, “low molecular weight” means a weight-average molecular weight (Mw) of 5,000 or less. On the other hand, in the present specification, “high molecular weight” means a weight average molecular weight (Mw) of more than 5,000. In the present specification, “weight-average molecular weight (Mw)” is a value measured through gel permeation chromatography (GPC) using polystyrene as the standard substance.

The high molecular weight host material is not particularly limited; examples thereof include poly(9-vinylcarbazole)(PVK), polyfluorene(PF), polyphenylene vinylene(PPV), and copolymers containing these monomer units.

The weight-average molecular weight (Mw) of the high molecular weight host material is preferably more than 5,000 and 5,000,000 or less, and more preferably more than 5,000 and 1,000,000 or less from the viewpoint of film formability.

The low molecular weight host material is not particularly limited; examples thereof include carbazole derivatives such as 4,4′-bis(9H-carbazol-9-yl)biphenyl (CBP), 4,4′-bis(9-carbazolyl)-2,2′-dimethylbiphenyl (CDBP), N,N′-dicarbazolyl-1,4-dimethylbenzene (DCB), 1,3-dicarbazolylbenzene (mCP), 3,5-bis(9-carbazolyl) tetraphenylsilane (SimCP), 9,9′-(p-tert-butylphenyl)-1,3-biscarbazole, silane derivatives such as 4,4′-di(di(triphenylsilyl)-biphenyl (BSB), 9-(4-tert-butylphenyl)-3,6-bis(triphenylsilyl)-9H-carbazol e (CzSi), and 1,3-bis(triphenylsilyl) benzene (UGH 3), metal complexes such as bis(2-methyl-8-quinolinolate)-4-(phenylphenolato)aluminum (BAlq), phosphine oxide derivatives such as 2,7-bis(diphenylphosphine oxide)-9,9-dimethylfluorescein (P06), amine derivatives such as 1,3,5-tris[4-(diphenylamino)phenyl]benzene (TDAPB), and heterocyclic compounds such as oxadiazole derivatives, imidazole derivatives, triazine derivatives, pyridine derivatives, and pyrimidine derivatives.

The weight-average molecular weight (Mw) of the low molecular weight host material is preferably 100 to 5,000, and more preferably 300 to 5,000 from the viewpoint of film formability.

Among the host materials, the host material to be used is preferably the low molecular weight host material, more preferably carbazole derivatives such as 4,4′-bis(9H-carbazol-9-yl)biphenyl (CBP) and 9,9′-(p-tert-butylphenyl)-1,3-biscarbazole, bis(2-methyl-8-quinolinolate)-4-(phenylphenolato)aluminum (BAlq), heterocyclic compounds such as oxadiazole derivatives, imidazole derivatives, triazine derivatives, pyridine derivatives, and pyrimidine derivatives, and even more preferably 4,4′-bis(9H-carbazol-9-yl)biphenyl (CBP), 9,9′-(p-tert-butylphenyl)-1,3-biscarbazole, and heterocyclic compounds such as imidazole derivatives, triazine derivatives, pyridine derivatives, and pyrimidine derivatives.

The host material may be used singly or two or more thereof may be used in combination.

The dopant material is usually classified into a high molecular weight dopant material and a low molecular weight dopant material.

There is no particular limitation on the high molecular weight dopant material; examples thereof include polyphenylene vinylene (PPV), cyanopolyphenylene vinylene (CN—PPV), poly(fluorenyleneethynylene) (PFE), polyfluorene (PFO), polythiophene polymer, polypyridine, and copolymers containing these monomer units.

The weight-average molecular weight (Mw) of the high molecular weight dopant material is preferably more than 5,000 and 5,000,000 or less, and more preferably more than 5,000 and 1,000,000 or less from the viewpoint of luminous efficiency.

The low molecular weight dopant material is not particularly limited; examples thereof include fluorescent materials, and phosphorescent materials.

Examples of the fluorescent material include naphthalene, perylene, pyrene, chrysen, anthracene, coumarin, p-bis(2-phenylethenyl)benzene, quinacridone, coumarin, aluminum complexes such as Al (C₉H₆NO)₃, rubrene, perimidone, dicyanomethylene-2-methyl-6-(p-dimethylaminostyryl)-4H-pyr an (DCM), benzopyran, rhodamine, benzothioxanthene, azabenzothioxanthene, and derivatives thereof.

Examples of the phosphorescent material include complexes in which a central metal belonging to Group 7 to Group 11 in the periodic table, and aromatic ligands coordinated to the central metal are included.

Examples of the central metal belong to Groups 7 to 11 in the periodic table include ruthenium, rhodium, palladium, osmium, iridium, gold, platinum, silver, and copper. Among those, the central metal is preferably iridium from the viewpoint of luminous efficiency.

Examples of the ligands include phenyl pyridine, p-tolylpyridine, thienylpyridine, difluorophenyl pyridine, phenylisoquinoline, fluorenopyridine, fluorenoquinoline, acetylacetone, and derivatives thereof. Among these, the ligand is preferably phenyl pyridine, p-tolylpyridine, and derivatives thereof, and more preferably p-tolylpyridine and derivatives thereof from the viewpoint of film formability.

Specific examples of the phosphorescent material include tris(2-phenylpyridine)iridium (Ir(ppy)₃), tris(2-phenylpyridine)ruthenium, tris(2-phenylpyridine)palladium, bis(2-phenylpyridine)platinum,tris(2-phenylpyridine)osmium, tris(2-phenylpyridine)rhenium, tris [2-(p-tolyl)pyridine]iridium (ir(mppy) ₃), tris [2-(p-tolyl)pyridine]ruthenium, tris [2-(p-tolyl)pyridine]palladium, tris [2-(p-tolyl)pyridine]platinum, tris [2-(p-tolyl)pyridine]osmium, tris[2-(p-tolyl)pyridine]rhenium, octaethyl platinum porphyrin, octaphenylplatinum porphyrin, octaethyl palladium porphyrin, and octaphenyl palladium porphyrin.

Among those, the dopant material is preferably the low molecular weight dopant material, and preferably the phosphorescent material from the viewpoint of luminous efficiency.

The weight-average molecular weight (Mw) of the low molecular weight dopant material is preferably 100 to 5,000, and is more preferably 100 to 3,000.

The dopant materials may be used singly and two or more thereof may be used in combination.

Among those, the light emitting material is preferably the low molecular weight light emitting materials and more preferably the low molecular host material and the low molecular dopant material from the viewpoint of obtaining a higher luminous efficiency.

(Hole Injection Material)

The hole injection material is not particularly limited; examples thereof include phthalocyanine compounds such as copper phthalocyanine; triphenylamine derivatives such as 4,4′-tris[phenyl (m-tolyl)amino]triphenylamine; cyano compounds such as 1,4,5,8,9,12-hexaazatriphenylene hexacarbonitrile and 2,3,5,6-tetrafluoro-7,7,8,8-tetracyano-quinodimethane; oxides such as vanadium oxides and molybdenum oxides; amorphous carbon; and polymers such as polyaniline (emeraldine), poly(3,4-ethylenedioxythiophene)-poly (styrenesulfonate) (PEDOT-PSS), and polypyrrole. Among these, the hole injection material is preferably a polymer, from the viewpoint of film formability.

The hole injection materials may be used singly, or two or more thereof may be used in combination.

(Hole Transport Material)

The hole transport material is not particularly limited; example thereof include low molecular weight triphenylamine derivatives such as TPD (N, N′-diphenyl-N, N′-di (3-methylphenyl)-1,1′-biphenyl-4,4′d iamine), αNPD (4,4′-bis[N-(1-naphthyl)-N-phenylamino]biphenyl), m-MTDATA (4,4′, 4″-tris (3-methylphenylphenylamino) triphenylamine); polyvinylcarbazole; and a polymer compound represented by the following chemical formula HT-2 obtained by polymerizing a triphenylamine derivative in which a substituent is introduced. Among these, the hole transport material is preferably triphenylamine derivative, and a polymer compound such as HT-2 represented by chemical formula 5 obtained by polymerizing a triphenylamine derivative in which a substituent is introduced from the viewpoint of hole transportability.

The hole transport materials maybe used singly and two or more thereof may be used in combination.

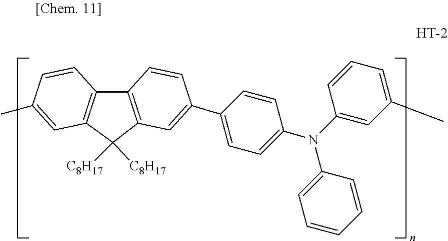

(Electron Transport Material)

There is no particular limitation on the electron transport material; examples thereof include metal complexes including quinoline skeleton or benzoquinoline skeleton such as tris(8-quinolilato)aluminum (Alq), tris(4-methyl-8-quinolinolato)aluminum (Almq3), bis(10-hydroxybenzo[h]quinolinato)beryllium (BeBq2), bis(2-methyl-8-quinolinolato)(p-phenylphenolato)aluminum (BAlq), bis(8-quinolinolato)zinc (Znq); metal complexes including benzoxazoline skeleton such as bis[2-(2′-hydroxyphenyl)benzoxazolate]zinc (Zn(BOX)2); metal complexes including a benzothiazoline skeleton such as bis[2-(2′-hydroxyphenyl)benzothiazolato]zinc (Zn(BTZ)2); polyazole derivatives such as 2-(4-biphenylyl)-5-(4-tert-butylphenyl)-1,3,4-oxadiazole(P BD), 3-(4-biphenylyl)-4-phenyl-5-(4-tent-butylphenyl)-1,2,4-tri azole (TAZ), 1,3-bis[5-(p-tert-butylphenyl)-1,3,4-oxadiazol-2-yl]benzen e(OXD-7), 9-[4-(5-phenyl-1,3,4-oxadiazol-2-yl)phenyl]carbazole (CO11), 2,2′,2″-(1,3,5-benzenetriyl)tris(1-phenyl-1H-benzimidazole) (TPBI), and 2-[3-(dibenzothiophen-4-yl)phenyl]-1-phenyl-1H-benzimidazo le (mDBTBIm-II); benzimidazole derivatives such as ET-1 represented by chemical formula 6; quinoline derivatives; perylene derivatives; pyridine derivatives; pyrimidine derivatives; triazine derivatives; quinoxaline derivatives; diphenylquinone derivatives; and nitro-substituted fluorene derivatives. Among these, the electron transport material is preferably the benzimidazole derivatives, the pyridine derivatives, the pyrimidine derivatives, and the triazine derivatives, from the viewpoint of electron transportability.

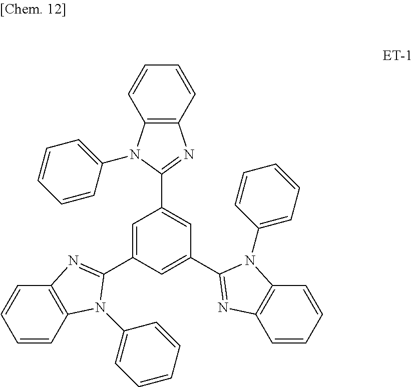 [SMILES: c1ccc(-n2c(-c3cc(-c4nc5ccccc5n4-c4ccccc4)cc(-c4nc5ccccc5n4-c4ccccc4)c3)nc3ccccc32)cc1]

The electron transport materials may be used singly, or two or more thereof may be used in combination.

(Solvent)

Any solvent considered as appropriate may be used without particular limitation. Specific examples thereof include aromatic solvents, alkane solvents, ether solvents, alcohol solvents, ester solvents, amide solvents, and other solvents.

Examples of the aromatic solvent include monocyclic aromatic solvents such as toluene, xylene, ethylbenzene, cumene, pentylbenzene, hexylbenzene, cyclohexylbenzene, dodecylbenzene, mesitylene, diphenylmethane, dimethoxybenzene, phenetol, methoxytoluene, anisole, methylanisole, and dimethylanisole; condensed cyclic aromatic solvents such as cyclohexylbenzene, tetralin, naphthalene, and methylnaphthalene; ether aromatic solvents such as methylphenylether, ethylphenylether, propylphenylether, and butylphenylether; and ester aromatic solvents such as phenyl acetate, phenyl propionate, ethyl benzoate, propyl benzoate, and butyl benzoate.

Examples of the alkane solvent include pentane, hexane, octane, and cyclohexane.

Examples of the ether solvent include dioxane, ethylene glycol dimethyl ether, ethylene glycol diethyl ether, propylene glycol-1-monomethyl ether acetate, and tetrahydrofuran.

Examples of the alcohol solvent include methanol, ethanol, and isopropyl alcohol.

Examples of the ester solvent include ethyl acetate, butyl acetate, ethyl lactate, and butyl lactate.

Examples of the amide solvent include N,N-dimethylformamide, and N,N-dimethylacetamide.

Examples of the other solvent include water, dimethyl sulfoxide, acetone, chloroform, and methylene chloride.

Among these, the solvent is preferably an aromatic solvent from the viewpoint of solubility of the organic semiconductor material, more preferably a solvent containing at least one selected from the group consisting of the condensed cyclic aromatic solvent, the ether aromatic solvent, and ester aromatic solvent from the viewpoint of leveling property, and even more preferably a solvent containing the condensed cyclic aromatic solvent and/or the ether aromatic solvent from the viewpoint of film formability.

The above described solvent may be used singly, or two or more thereof may be used in combination.

In a case where a coating film is formed by applying the electronic material composition according to the embodiment, the presence of the siloxane structure in the polymer of the present invention, which serves as a leveling agent, causes the polymer to be aligned on the surface of the coating film and lowers the surface tension. In the case of drying the coating film obtained in such a state, undulation due to drying can be prevented, and a layer having a high degree of flatness, further, an organic functional layer exhibiting excellent performance can be provided.

In one embodiment, in a case where the electronic material composition in forming the light emitting layer of the organic EL element is used, the material composition even plays a role of improving the driving stability of the organic EL element. Such a function is believed to be exhibited because of charges attributable to the hetero ring structure in the polymer.

More specifically, in one embodiment, the light emitting material includes the host material and the dopant material. In the light emitting layer, the holes and/or electrons are transported through the host material, and the energy generated by recombination of holes and electrons transported to the dopant material causes the light emitting layer to emit light. In other words, once the holes and the electrons in the light emitting layer are efficiently transported, efficient light emission is enabled, thereby improving the driving stability.

The conventional level agents, which is incorporated in an electronic material composition, are aligned on the surface of the coating film obtained by coating an ink composition, and decrease the surface tension, thereby enabling production of smooth coating film. However, the presence of functional groups such as an aralkyl group with a charge, a polyether group, and a carbonyl group that may inhibit electron injection therein may deteriorate the charge balance in the light emitting layer, and impair light emitting efficacy and driving stability of the element. That is, a certain degree of undulation preventing effect may be achieved by using the conventional leveling agents, but the light emitting efficacy and driving stability may decrease instead.

On the other hand, incorporation of hetero ring into a leveling agent decreases electron injection barrier as compared with the conventional leveling agents, thereby preventing inhibition of electron transfer. As a result, charges in the light emitting layer are efficiently transferred, and thus the light emitting efficacy and driving stability of an element can be improved.

[Electronic Element]

The electronic element of the present invention will be described. The electronic element of the present invention is an electronic element which contains a composition or an electronic material composition containing the polymer of the present invention, in any form. Specific examples of the electronic element include photoelectric conversion elements such as a solar cell or a light receiving element, transistors such as a field effect transistor, static induction transistor and bipolar transistor, organic electroluminescent elements (hereinafter abbreviated as “organic EL element”), a temperature sensor, a gas sensor, a humidity sensor, and a radiation sensor, but are not limited thereto.

As an example, the organic EL element will be described below.

<Organic EL Element>

According to one aspect of the present invention, there is provided an organic EL element including an anode, a light emitting layer, and a cathode. In this case, the light emitting layer is formed of an electronic material composition.

The organic EL element may include one or more other layers such as a hole injection layer, a hole transport layer, an electron transport layer, and an electron injection layer. Also, commonly known elements such as a sealing member may further be included.

According to another embodiment, there is provided an organic EL element including an anode, a light emitting layer, and a cathode, and at least one layer selected from the group consisting of a hole injection layer, a hole transport layer, an electron transport layer, and an electron injection layer. In this case, at least one layer selected from the group consisting of the light emitting layer, the hole injection layer, the hole transport layer, and the electron transport layer included in the organic EL element includes the polymer (leveling agent) of the present invention.

That is, the organic EL element includes the anode, the light emitting layer, and the cathode as essential constitutional units, and may further include at least one layer selected from the group consisting of the hole injection layer, the hole transport layer, the electron transport layer, and the electron injection layer as an optional structural unit. In this case, the leveling agent may be included only in the light emitting layer, or may be included only in at least one layer selected from the group consisting of the hole injection layer, the hole transport layer, and the electron transport layer (for example, only in the hole transport layer, or in the hole transport layer and the electron transport layer), or may be included in at least one layer of the light emitting layer, the hole injection layer, the hole transport layer, and the electron transport layer. In this case, it is preferable that the light emitting layer and/or the hole transport layer include the leveling agent, and it is more preferable that the light emitting layer includes the leveling agent. Each of the constituents of the organic EL element will be described in detail below.

[Anode]

There is no particular limitation on the anode; examples of materials that may be used for the anode include metals such as gold (Au), and copper iodide (CuI), indium tin oxide (ITO), tin oxide (SnO₂), and zinc oxide (ZnO). These materials may be used singly, or two or more thereof may be used in combination.

Although there is no particular limitation on the film thickness of the anode, the thickness is preferably 10 nm to 1,000 nm, and more preferably 10 nm to 200 nm.

The anode may be formed through methods such as vapor deposition or sputtering. In this case, the pattern may be formed through a photolithography method or a method using a mask.

[Hole Injection Layer]

The hole injection layer is an optional constitutional element in the organic light emitting element and has a function of accepting the holes from the anode. Usually, the holes accepted from the anode are transported to the hole transport layer or the light emitting layer.

The material that may be used for the hole injection layer is the same as those described above, and hereby the detailed description will be omitted.

Although there is no particular limitation on the film thickness of the hole injection layer, the film thickness is preferably 0.1 nm to 5 μm.

The hole injection layer may be formed of a single layer, or two or more laminated layers.

The hole injection layer may be formed through a wet film formation method or a dry film formation method.

In a case where the hole injection layer is formed through the wet film formation method, usually, a step of applying an ink composition for the organic light emitting element, and a step of drying the obtained coating film are included. In this case, there is no particular limitation on the coating method; examples thereof include an ink jet printing method, a letterpress printing method, a gravure printing method, a screen printing method, and a nozzle print printing method.

In a case where the hole injection layer is formed through the dry film formation method, the vacuum deposition method, the spin coating method, or the like may be applied.

[Hole Transport Layer]

The hole transport layer is an optional constitutional element in the organic light emitting element and has a function of efficiently transporting the holes. The hole transport layer may further have a function of preventing the hole transport. The hole transport layer usually accepts the holes from the anode or the hole injection layer, and transports the holes to the light emitting layer.

The material that may be used for the hole transport layer is the same as those described above, and hereby the detailed description will be omitted.

Although there is no particular limitation on the film thickness of the hole transport layer, the film thickness is preferably 1 nm to 5 μm, more preferably 5 nm to 1 μm, and even more preferably 10 nm to 500 nm.

The hole transport layer may be formed of a single layer, or two or more laminated layers.

The hole transport layer can be formed through a wet film formation method or a dry film formation method.

In a case where the hole transport layer is formed by the wet film formation method, usually a step of applying an ink composition for the organic light emitting element, and a step of drying the obtained coating film are included. In this case, there is no particular limitation on the coating method; examples thereof include an ink jet printing method, a letterpress printing method, a gravure printing method, a screen printing method, and a nozzle print printing method.

In a case where the hole transport layer is formed through the dry film formation method, the vacuum deposition method, the spin coating method, or the like may be applied.

[Light Emitting Layer]

The light emitting layer has a function of generating light emission using the energy generated by recombination of the holes and the electrons injected into the light emitting layer.

The materials that may be used for the light emitting layer are the same as those described above, and hereby the detailed description will be omitted.

Although there is no particular limitation on the film thickness of the light emitting layer, the film thickness is preferably 2 nm to 100 nm, and more preferably 2 nm to 20 nm.

The light emitting layer may be formed through a wet film formation method or a dry film formation method.

In a case where the light emitting layer is formed by the wet film formation method, usually, a step of applying the ink composition for the organic light emitting element, and a step of drying the obtained coating film are included. In this case, there is no particular limitation on the coating method; examples thereof include an ink jet printing method, a letterpress printing method, a gravure printing method, a screen printing method, and a nozzle print printing method.

In a case where the light emitting layer is formed through the dry film formation method, the vacuum deposition method, the spin coating method or the like may be applied.

[Electron Transport Layer]

The electron transport layer is an optional constituent element in the organic light emitting element, and has a function of efficiently transporting the electrons. The electron transport layer may further have a function of preventing the electron transport. The electron transport layer usually accepts the electrons from the cathode or the electron injection layer, and transports the electrons to the light emitting layer.

The material that may be used for the electron transport layer is the same as those described above, and hereby the detailed description will be omitted.

Although there is no particular limitation on the film thickness of the electron transport layer, the film thickness is preferably 5 nm to 5 μm, and more preferably 5 nm to 200 nm.

The electron transport layer may be formed of a single layer, or two or more laminated layers.

The electron transport layer may be formed through a wet film formation method or a dry film formation method.

In a case where the electron transport layer is formed through the wet deposition method, usually, a step of applying the ink composition for the organic light-emitting element, and a step of drying the obtained coating film are included. In this case, there is no particular limitation on the coating method, and examples thereof include an inkjet printing method, a letterpress printing method, a gravure printing method, a screen printing method, and a nozzle print printing method.

In a case where the electron transport layer is formed through the dry film formation method, the vacuum deposition method, or the spin coating method may be applied.

[Electron Injection Layer]

The electron injection layer is an optional constitutional element in the organic light emitting element, and has a function to accept the electrons from the cathode. Usually, the electrons accepted from the cathode are transported to the electron transport layer or the light emitting layer.

There is no particular limitation on the electron injection material; examples thereof include alkali metals such as lithium and calcium; metals such as strontium and aluminum; alkali metal salts such as lithium fluoride and sodium fluoride; alkali metal compounds such as 8-hydroxyquinliolato-lithium; alkaline earth metal salts such as magnesium fluoride; and oxides such as aluminum oxide. Among these, the electron injection material is preferably an alkali metal, an alkali metal salt, or an alkali metal compound, and more preferably an alkali metal salt, or an alkali metal compound.

These electron injection materials may be used singly, or two or more thereof may be used in combination.

Although there is no particular limitation on the film thickness of the electron injection layer, the film thickness is preferably 0.1 nm to 5 μm.

The electron injection layer may be formed of a single layer, or two or more laminated layers.

The electron injection layer may be formed through a wet film formation method or a dry film formation method.

In a case where the electron injection layer is formed through the wet deposition method, usually, a step of applying the ink composition for the organic light-emitting element, and a step of drying the obtained coating film are included. In this case, there is no particular limitation on the coating method, examples thereof include an ink jet printing method, a letterpress printing method, a gravure printing method, a screen printing method, and a nozzle print printing method.

In a case where the electron injection layer is formed through the dry film formation method, the vacuum deposition method, the spin coating method, or the like may be applied.

[Cathode]

There is no particular limitation on materials that may be used for the cathode; examples thereof include lithium, sodium, magnesium, aluminum, sodium-potassium alloy, magnesium/aluminum mixture, magnesium/indium mixture, aluminum/aluminum oxide (Al₂O₃) mixture, and rare earth metals. These materials may be used singly, or two or more thereof may be used in combination.

Usually, the cathode can be formed through a method such as vapor deposition or sputtering.

Although there is no particular limitation on the film thickness of the cathode, the film thickness is preferably 10 to 1,000 nm, and more preferably 10 to 200 nm.

In one embodiment, the organic EL element includes a layer formed using the electronic material composition such that ununiformity in the film thickness of the layer to be formed can be suitably prevented. This allows the obtainable organic EL element to have high performance such as prevention of luminance dispersion or the like.

In another embodiment, the light emitting layer is formed using the electronic material composition. This enables the resulting organic EL element to exhibit excellent luminous efficiency and driving stability.

### EXAMPLES

Hereinafter, detailed description of the present invention will be provided with reference to Examples, but the present invention is not limited to the description of the working examples.

<Synthesis of Hetero ring-Containing Monomer>

Synthesis Example 1

### Synthesis of A-1

The synthesis scheme of A-1 is shown below.

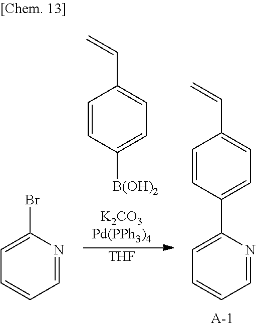

Potassium carbonate 2 M aqueous solution (7.6 mL) was added to THF (15 mL), and 2-bromopyridine (2.3 g, 14.8 mmol), 4-vinylphenylboronic acid (1.5 g, 10.3 mmol) were further added thereto under nitrogen atmosphere. Then, tetrakis(triphenylphosphine)palladium(0) (9.5 mg, 8.2 μmol) was added thereto, and the mixture was stirred at 80° C. for 12 hours. The reaction solution was cooled to room temperature, dichloromethane and water were added thereto, the organic layer was separated therefrom, and the organic layer was dried over magnesium sulfate, and the organic solvent was distilled off under reduced pressure. The obtained residue was purified by silica gel chromatography to obtain Hetero ring-containing monomer A-1 (1.0 g, 53%).

### Synthesis Example 2

### Synthesis of A-2

The synthesis scheme is shown below.

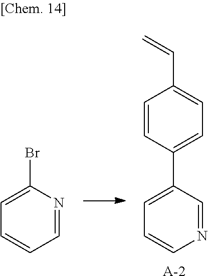

Hetero ring-containing monomer A-2 (0.81 g, 44%) was obtained in the same manner as in Synthesis Example 1 except that 2-bromopyridine was replaced with 3-bromopyridine.

### Synthesis Example 3

### Synthesis of A-3

The synthesis scheme is shown below.

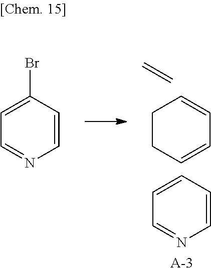

Hetero ring-containing monomer A-3 (0.8 g, 43%) was obtained in the same manner as in Synthesis Example 1 except that 2-bromopyridine was replaced with 3-bromopyridine.

### Synthesis Example 4

### Synthesis of A-4

The synthesis scheme is shown below.

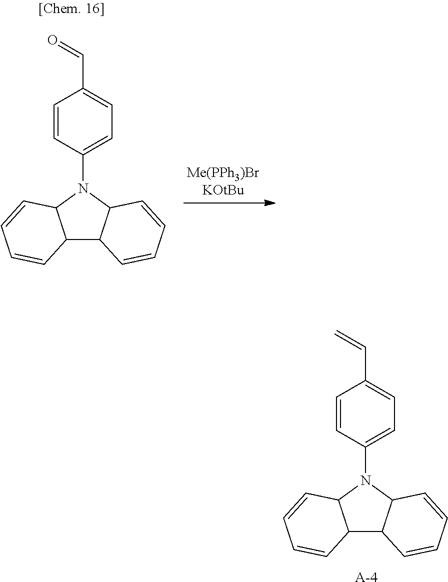

Potassium tert-butoxide (1.02 g, 9.15 mmol) and methyltriphenylphosphonium bromide (3.11 g, 8.71 mmol) were added to dehydrated THF (20.8 mL) at 0° C. under a dry nitrogen atmosphere, and the mixture was stirred for 15 minutes. Thereafter, N-(4-formylphenyl)carbazole (1.20 g, 4.36 mmol) dissolved in dehydrated THF (20.8 mL) was added dropwise thereto, and the mixture was stirred at 0° C. for 3 hours. Subsequently, the mixture was further stirred at room temperature for 4 hours, and then an ammonium chloride aqueous solution and dichloromethane were added thereto, and the organic layer was separated therefrom, and the organic layer was dried over magnesium sulfate, and the organic solvent was distilled off under reduced pressure. The obtained residue was purified by silica gel chromatography to obtain Hetero ring-containing monomer A-5 (0.43 g, 36%).

### Synthesis Example 5

### Synthesis of A-5

The synthesis scheme is shown below.

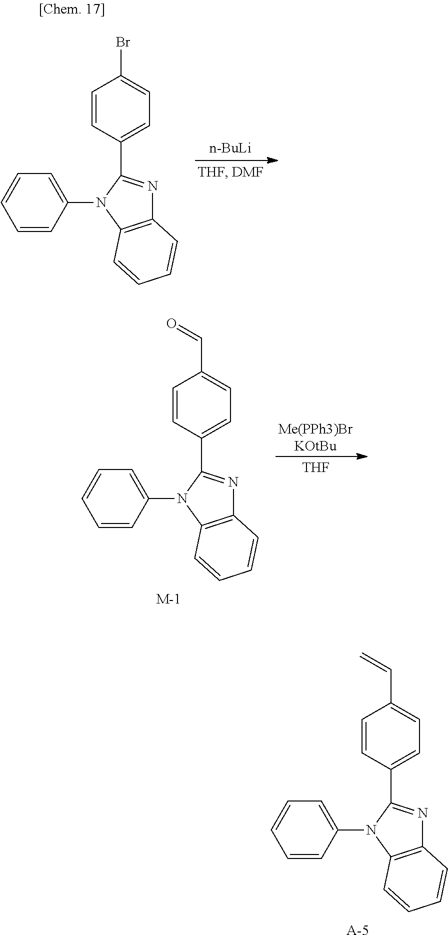

(Synthesis of M-1)

2-(4-bromophenyl)-1-phenylbenzimidazole (3.00 g, 8.59 mmol) was added to dehydrated THF (35.0 mL) under a dry nitrogen atmosphere, and after cooling to −78° C., n-butyllithium 1.6 M THF solution (6.4 g, 10.31 mmol) was added dropwise thereto. After stirring for 2 hours, dehydrated DMF (4.0 mL) was added and the mixture was stirred at 25° C. for 1 hour. Subsequently, after refluxing for 1 hour, the reaction solution was cooled to room temperature, aqueous ammonium chloride solution and dichloromethane were added thereto, and the organic layer was separated therefrom. After drying the organic layer over magnesium sulfate, the organic solvent was distilled off under reduced pressure. The obtained residue was purified by silica gel chromatography to obtain Intermediate monomer M-1 (1.18 g, 46%).

(Synthesis of A-5)

Hetero ring-containing monomer A-6 (0.45 g, 38%) was obtained in the same manner as in Synthesis Example 4 except that N-(4-formylphenyl)carbazole was replaced with M-1 (1.18 g, 3.95 mmol).

### Synthesis Example 6

### Synthesis of A-6

The synthesis scheme is shown below.

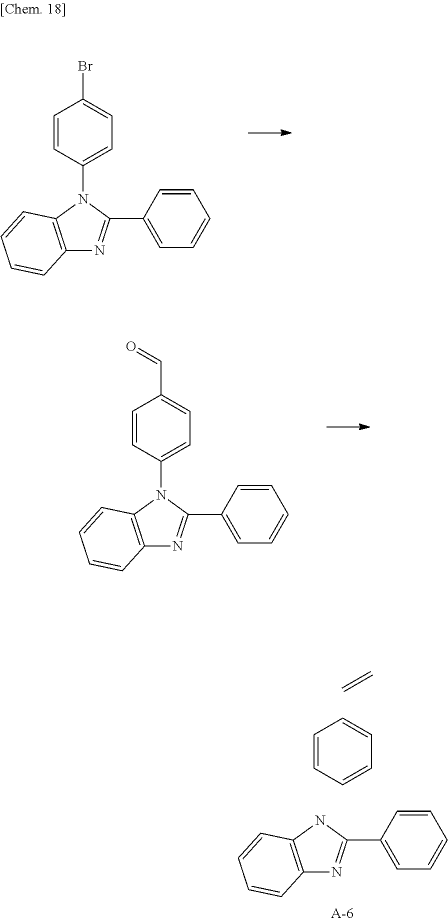

Hetero ring-containing monomer A-6 (0.36 g, 30%) was obtained in the same manner as in Synthesis Example 5 except that 2-(4-bromophenyl)-1-phenylbenzimidazole was replaced with 1-(4-bromophenyl)-2-phenylbenzimidazole.

### Synthesis Example 7

### Synthesis of A-7

The synthesis scheme is shown below.

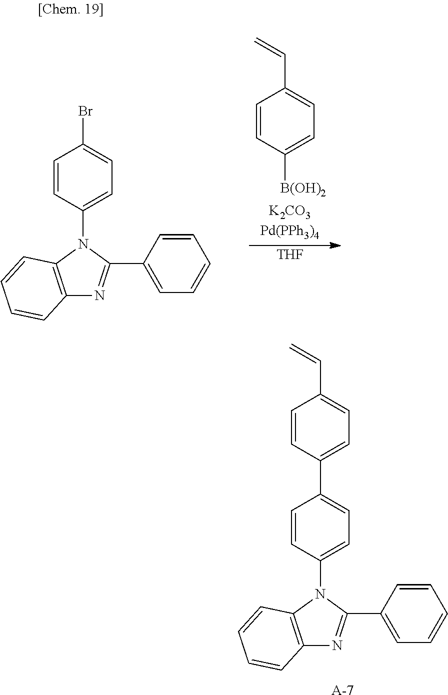

Hetero ring-containing monomer A-7 (2.5 g, 46%) was obtained in the same manner as in Synthesis Example 1 except that 2-bromopyridine was replaced with 1-(4-bromophenyl)-2-phenylbenzimidazole.

### Synthesis Example 8

### Synthesis of A-8

The synthesis scheme is shown below.

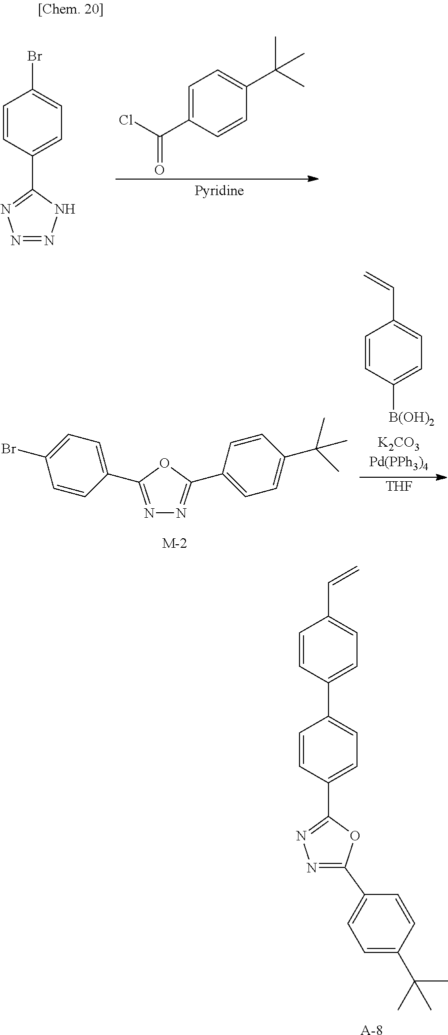

(Synthesis of M-2)

Benzoyl chloride (0.96 g, 4.88 mmol) was added to pyridine (14 mL), followed by the addition of 5-(4-bromophenyl)-1H-tetrazole (1.0 g, 4.44 mmol). After stirring at 100° C. for 8 hours, the reaction solution was cooled to room temperature, water was added thereto, and the precipitate was filtered. The residue was recrystallized with ethanol to obtain Intermediate monomer M-2 (0.8 g, 52%).

(Synthesis of A-8)

Potassium carbonate 2 M aqueous solution (2.0 mL) was added to THF (10 mL), and M-2 (0.8 g, 2.31 mmol) and 4-vinylphenylboronic acid (0.26 g, 1.76 mmol) were further added thereto under nitrogen atmosphere. Subsequently, tetrakis(triphenylphosphine)palladium(0) (9.5 mg, 8.2 μmol) was added and the mixture was stirred at 80° C. for 12 hours. The reaction solution was cooled to room temperature, dichloromethane and water were added thereto, the organic layer was separated therefrom, and the organic layer was dried over magnesium sulfate, and the organic solvent was distilled off under reduced pressure. The obtained residue was purified by silica gel chromatography to obtain Hetero ring-containing monomer A-8 (0.38 g, 43%).

### Synthesis Example 9

### Synthesis of A-9

The synthesis scheme is shown below.

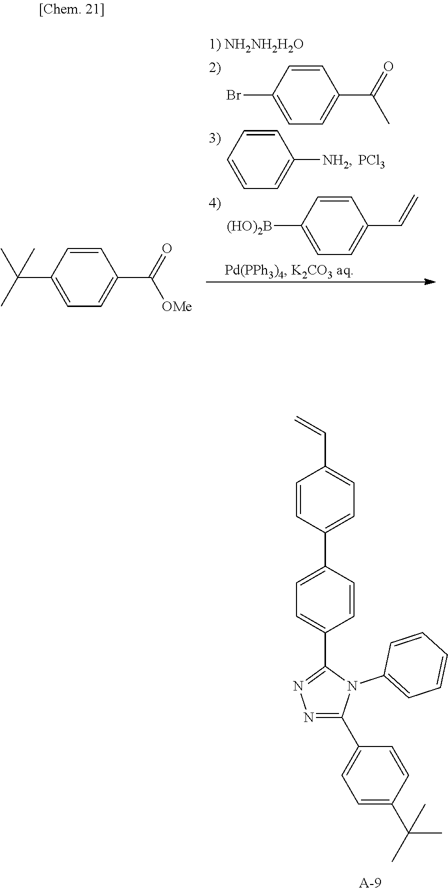

Methyl 4-tert-butylbenzoate (1.8 g, 9 mmol) was dissolved in ethanol (25 mL), hydrazine monohydrate (10 g, 20 mmol) was added, and the mixture was heated under reflux for 10 hours. The obtained reaction mixture was poured into water, and the solid was collected by filtration and dried. 20 mL of pyridine and 4-bromobenzoyl chloride (2.2 g, 10 mmol) were added thereto, and the mixture was stirred at room temperature for 5 hours. The obtained solution was poured into water, and the solid was collected by filtration and dried. 10 mL of o-dichlorobenzene, aniline (0.9 g, 9.5 mmol) and phosphorus trichloride (3.3 g, 23.5 mmol) were added to the solid, and the mixture was heated under reflux for 3 hours. The reaction solution was poured into water, and organic compounds were extracted with chloroform. After distilling off the extract under reduced pressure, 1,2-dimethoxyethane (25 mL), 4-vinylphenylboronic acid (1.5 g, 10 mmol), tetrakis(triphenylphosphine)palladium (0.12 g, 0.10 mmol), and 50 mL of an aqueous solution of sodium carbonate (3.2 g, 29.5 mmol) were added, and the mixture was heated under reflux for 3 hours. After cooling the reaction solution to room temperature, the organic layer was distilled off under reduced pressure and purified by silica gel column chromatography to obtain Compound A-9 (1.4 g, 34%).

### Synthesis Example 10

### Synthesis of A-10

The synthesis scheme is shown below.

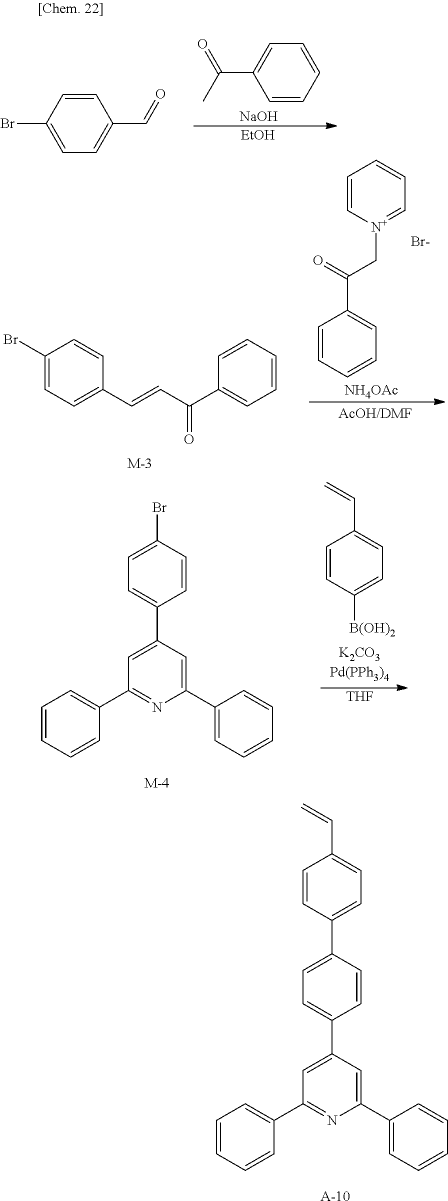

(Synthesis of M-3)

4-Bromobenzaldehyde (25g, 135 mmol), acetophenone (16.2 g, 135 mmol) were added to ethanol, 3 M potassium hydroxide aqueous solution (60 mL) was further added thereto, and the mixture was stirred at room temperature for 7 hours. The precipitated solid was filtered, and this solid was washed with methanol to obtain M-3 (25.5 g, 66%).

(Synthesis of M-4)

M-3 (5 g, 17.4 mmol), phenacylpyridinium bromide (7.6 g, 27.3 mmol), ammonium acetate (27 g), acetic acid (120 mL), and N,N-dimethylformamide (120 mL) were refluxed for 8 hours under heating reflux. The reaction solution was poured into ice water, the precipitate was filtered and washed with methanol. The obtained solid was purified by silica gel chromatography to obtain M-4 (2.3 g, 44%).

(Synthesis of A-10)

Potassium carbonate 2 M aqueous solution (2.0 mL) was added to THF (10 mL), and M-4 (2.3 g, 6.0 mmol), and 4-vinylphenylboronic acid (0.8 g, 5.6 mmol) were further added under nitrogen atmosphere. Then, tetrakis(triphenylphosphine)palladium(0) (9.5 mg, 8.2 μmol) was added thereto, and the mixture was stirred at 80° C. for 12 hours. The reaction solution was cooled to room temperature, dichloromethane and water were added thereto, the organic layer was separated therefrom, and the organic layer was dried over magnesium sulfate, and the organic solvent was distilled off under reduced pressure. The obtained residue was purified by silica gel chromatography to obtain Hetero ring-containing monomer A-10 (1.0 g, 41%).

### Synthesis Example 11

### Synthesis of A-11

The synthesis scheme is shown below.

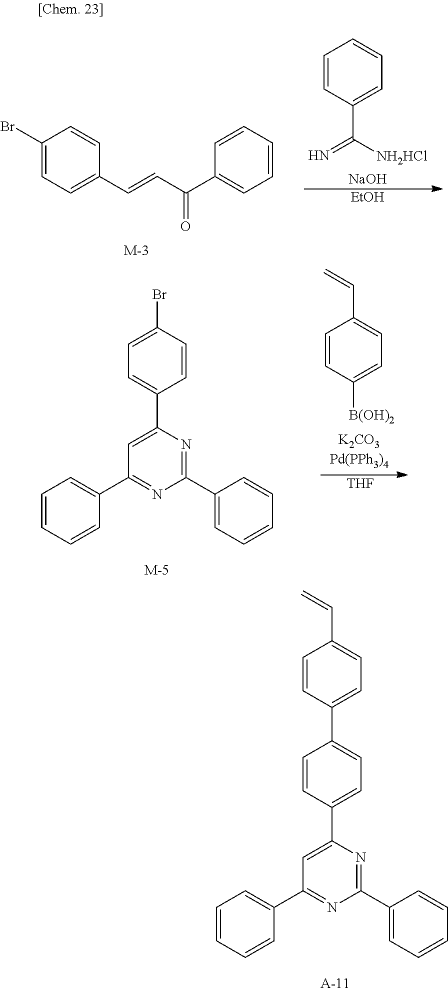

(Synthesis of M-5)

M-3 (5 g, 17.4 mmol), benzamidine hydrochloride (2.7 g, 17.4 mmol) were added to ethanol (75 mL), and sodium hydroxide (1.4 g, 35 mmol) was further added thereto, and the mixture was heated under reflux for 8 hours. The precipitated solid was filtered, and the solid was washed with hexane to obtain M-5 (2.3 g, 35%).

(Synthesis of A-11)

Hetero ring-containing monomer A-11 (1.0 g, 41%) was obtained in the same manner as in Synthesis Example 10 except that M-4 was replaced with M-5.

### Synthesis Example 12

### Synthesis of A-12

The synthesis scheme is shown below.

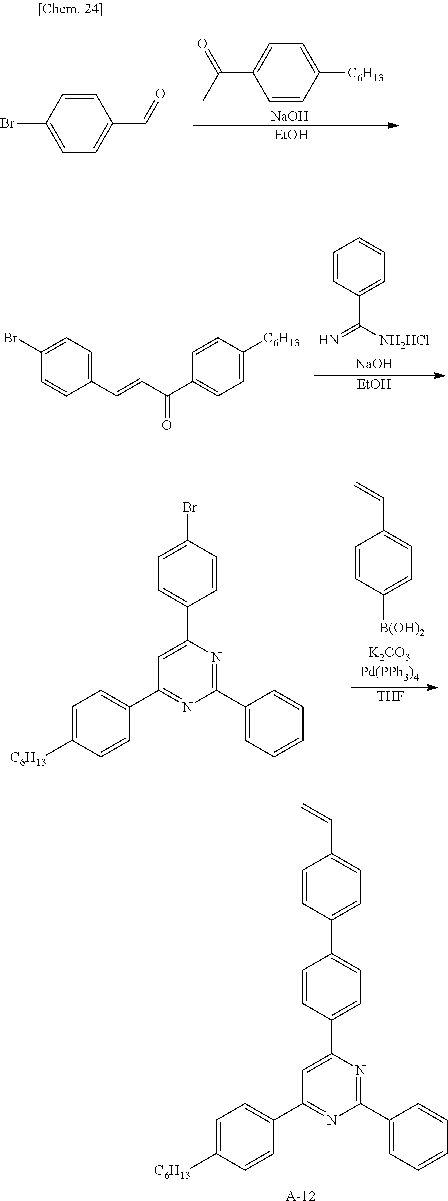

Hetero ring-containing monomer A-12 (0.8 g, 9%) was obtained in the same manner as in Synthesis Example 10 except that acetophenone was replaced with 4′-hexylacetophenone.

### Synthesis Example 13

### Synthesis of A-13

The synthesis scheme is shown below.

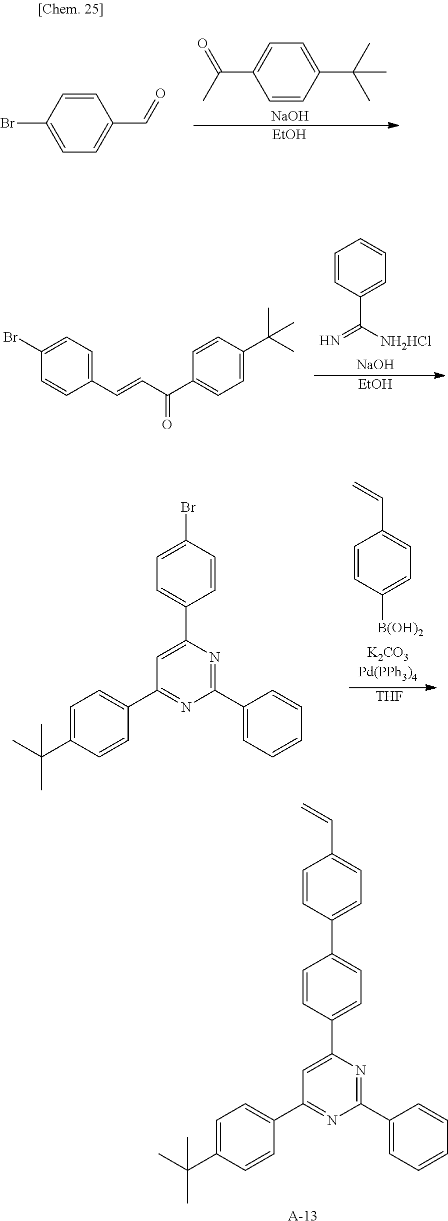

Hetero ring-containing monomer A-13 (1.0 g, 12%) was obtained in the same manner as in Synthesis Example 10 except that acetophenone was replaced with 4′-tert-acetophenone.

### Synthesis Example 14

### Synthesis of A-14

The synthesis scheme is shown below.

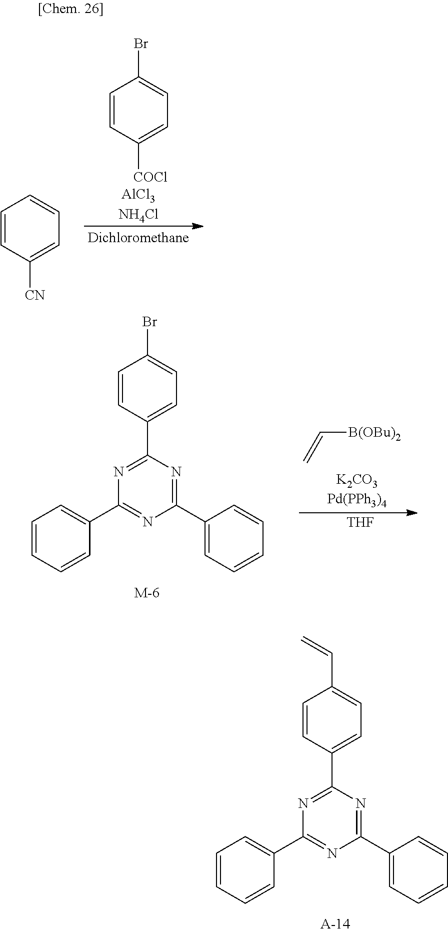

4-Bromobenzoyl chloride (2.2 g, 10 mmol) and benzonitrile (3.1 g, 30 mmol) were dissolved in 50 mL of dichloroethane, aluminum chloride (1.3g, 10 mmol) and ammonium chloride (2.1 g, 40 mmol) were added thereto, and the mixture was heated under reflux for 24 hours. After cooling to room temperature, the reaction solution was poured into 10% hydrochloric acid and stirred for 1 hour. The mixture was extracted with chloroform and purified by column chromatography to obtain M-6 (1.6 g, 40%).

A 100 mL eggplant type flask was charged with M-6 (1.4 g, 3.6 mmol), vinyl borate dibutyl ester (0.61 g, 3.3 mmol), and tetrabutylammonium bromide (0.42 g, 1.5 mmol), and 45 mL of toluene and 30 ml of 2 M aqueous potassium carbonate solution were added thereto. A small amount of a polymerization inhibitor was added to the solution, and tetrakis(triphenylphosphine)palladium(0) (0.17 g, 0.15 mmol) was further added thereto, followed by heating under reflux for 3 hours. After cooling to room temperature, extraction with ethyl acetate was carried out, and column chromatography and recrystallization operation were performed to obtain Heterocyclic monomer A-14 (0.53 g, 48%).

### Synthesis Example 15

### Synthesis of A-15

The synthesis scheme is shown below.

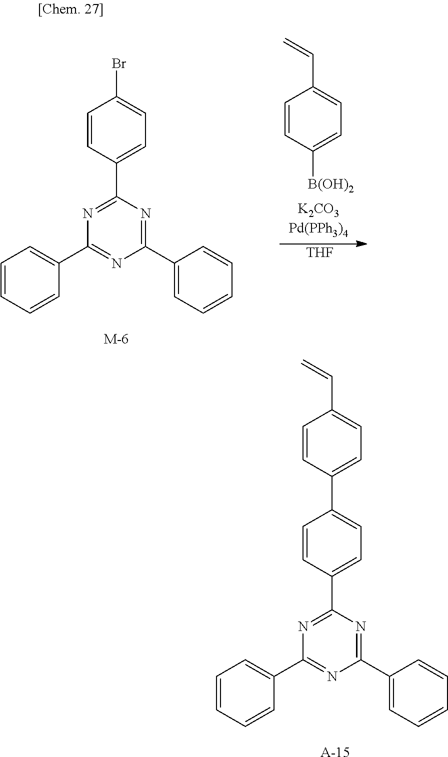 [SMILES: Brc1ccc(-c2nc(-c3ccccc3)nc(-c3ccccc3)n2)cc1 ; C=Cc1ccc(B(O)O)cc1 ; "M-6" ; C=Cc1ccc(-c2ccc(-c3nc(-c4ccccc4)nc(-c4ccccc4)n3)cc2)cc1 ; "THF" ; "A-15"]

Hetero ring-containing monomer A-15 (3.0 g, 42%) was obtained in the same manner as in Synthesis Example 10 except that M-4 was replaced with M-6.

### Synthesis Example 16

### Synthesis of A-16

The synthesis scheme is shown below.

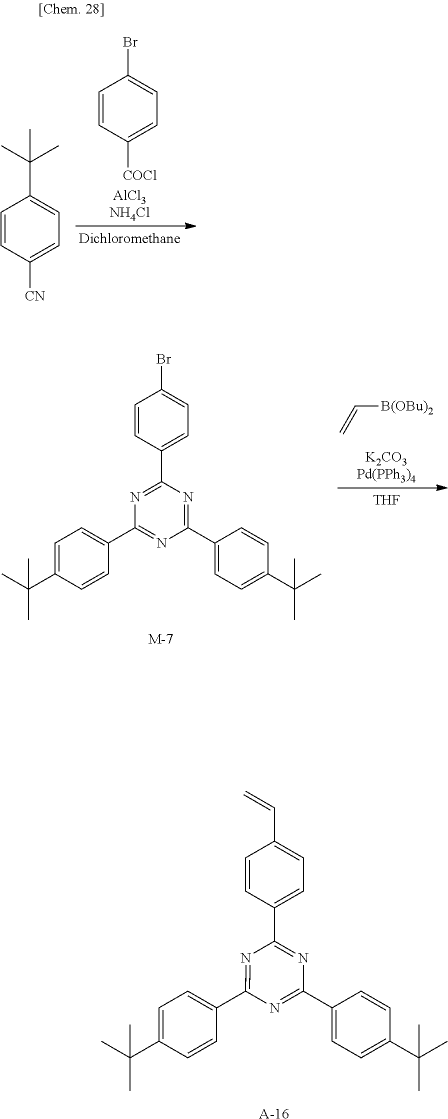

Hetero ring-containing monomer A-16 (0.7 g, 19%) was obtained in the same manner as in Synthesis Example 14 except that benzonitrile was replaced with 4-tert-butylbenzonitrile.

### Synthesis Example 17

### Synthesis of A-17

The synthesis scheme is shown below.

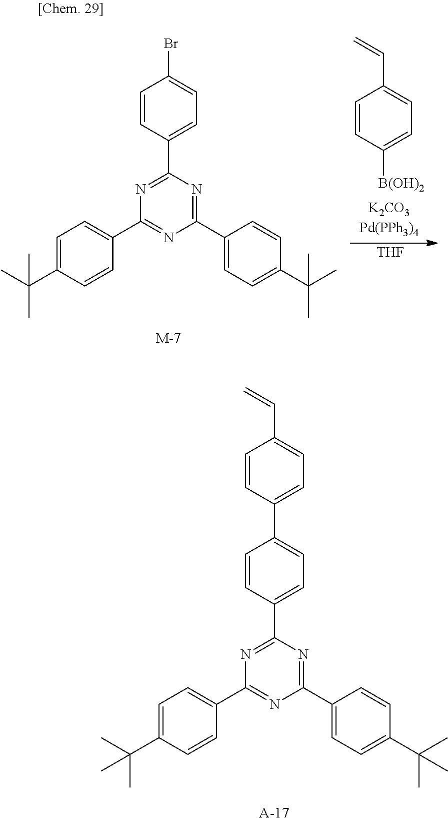

Hetero ring-containing monomer A-17 (1.3 g, 41%) was obtained in the same manner as in Synthesis Example 10 except that M-4 was replaced with M-7.

### Synthesis Example 18

<Synthesis of Siloxane Monomer B-1>

The scheme for synthesis is shown below.

100 g of SILAPLANE FM-0411 (manufactured by JNC Corporation) and 16.8 g of potassium tert-butoxide were charged into a 500 mL three-necked flask, which was purged with argon gas and into which 100 g of tetrahydrofuran (THF) was inserted, and the mixture was stirred at room temperature for an hour. 11.8 g of 5-bromo-1,3-pentadiene was added dropwise thereto, and the mixture was stirred at room temperature for 18 hours. Thereafter, THF was distilled off under reduced pressure, and the mixture was extracted with toluene, and the obtained product was washed three times with water, and then dried over sodium sulfate. Thereafter, the mixture was purified through silica gel column chromatography so as to obtain Siloxane monomer B-1. The yield was 18 g.

The structure of Siloxane Monomer B-1 is shown below.

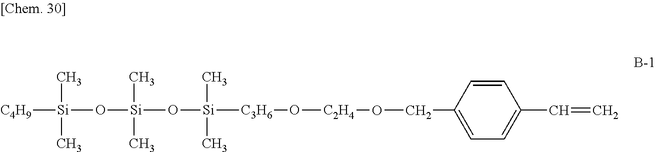

<Synthesis of Polymer>

### Examples 1 to 19

500 mg of Heterocyclic monomers A-1 to A-19 and SILAPLANE FM-0711 (manufactured by JNC Corporation), 19.7 mg of PERBUTYL Z (manufactured by NOF Corporation), and 2.4 g of cyclohexanone were placed in a 10 mL three-necked flask, and the mixture was stirred at 110° C. for 30 hours under nitrogen gas charging. The obtained reaction solution was added dropwise to methanol so as to precipitate the polymer, and the polymer was collected by filtration and dried to obtain Polymers P-1 to 19 of the present invention.

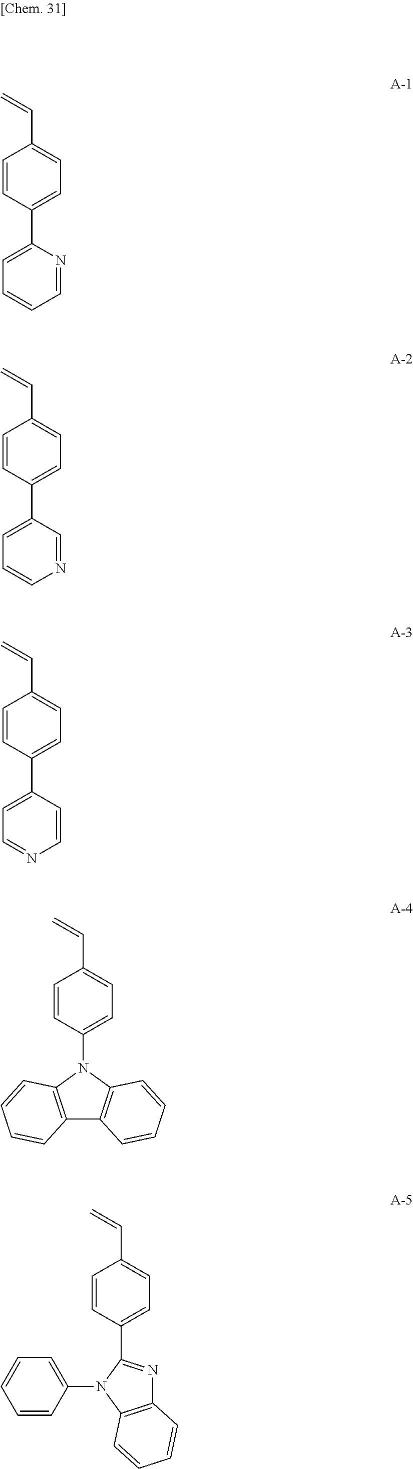 [SMILES: C=Cc1ccc(-c2ccccn2)cc1 ; C=Cc1ccc(-c2cccnc2)cc1 ; C=Cc1ccc(-c2ccncc2)cc1 ; C=Cc1ccc(-n2c3ccccc3c3ccccc32)cc1 ; C=Cc1ccc(-c2nc3ccccc3n2-c2ccccc2)cc1]

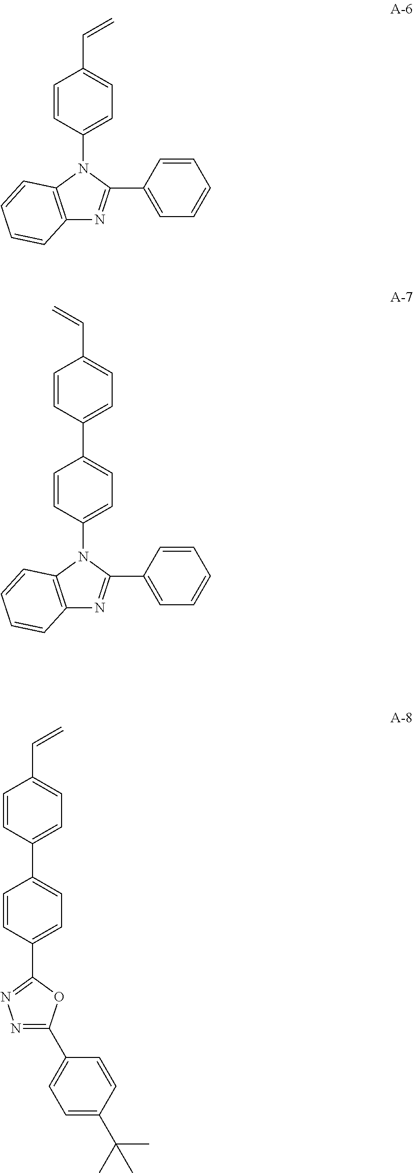 [SMILES: C=Cc1ccc(-n2c(-c3ccccc3)nc3ccccc32)cc1 ; C=Cc1ccc(-c2ccc(-n3c(-c4ccccc4)nc4ccccc43)cc2)cc1 ; C=Cc1ccc(-c2ccc(-c3nnc(-c4ccc(C(C)(C)C)cc4)o3)cc2)cc1]

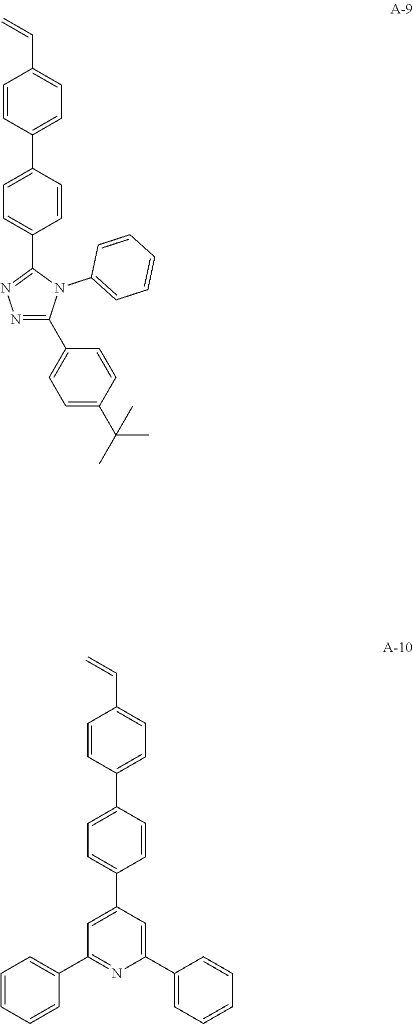 [SMILES: C=Cc1ccc(-c2ccc(-c3nnc(-c4ccc(C(C)(C)C)cc4)n3-c3ccccc3)cc2)cc1 ; C=Cc1ccc(-c2ccc(-c3cc(-c4ccccc4)nc(-c4ccccc4)c3)cc2)cc1]

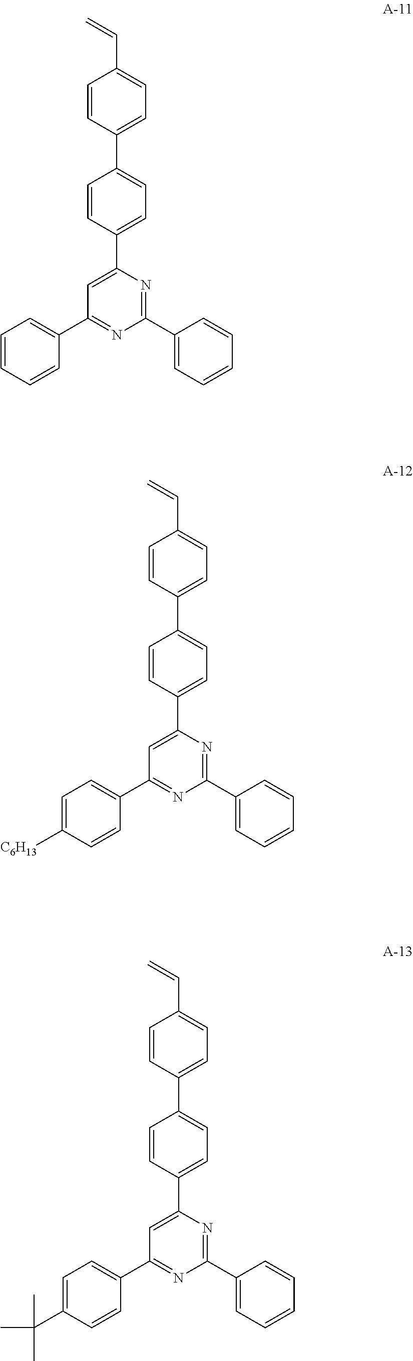

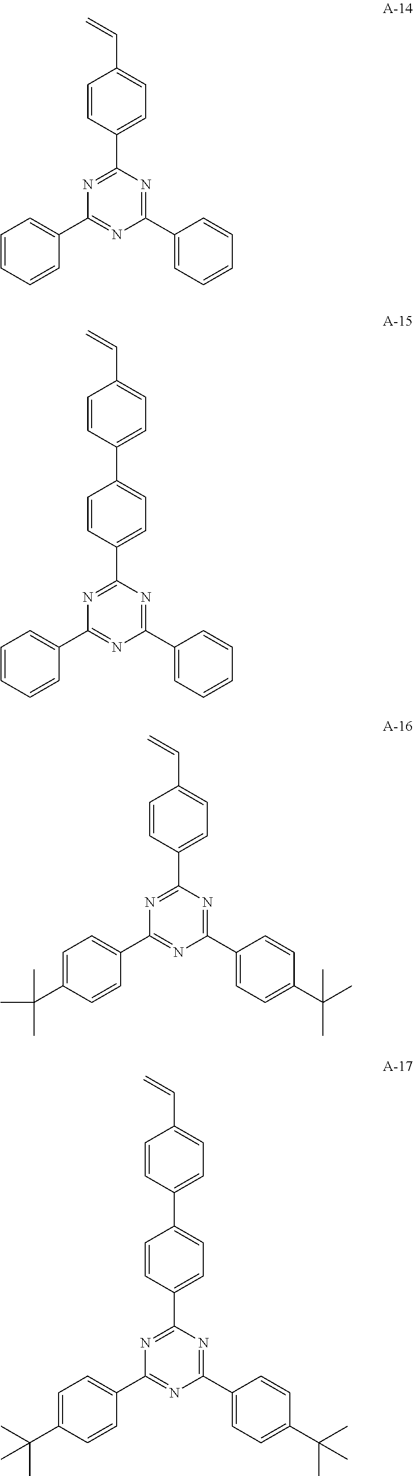

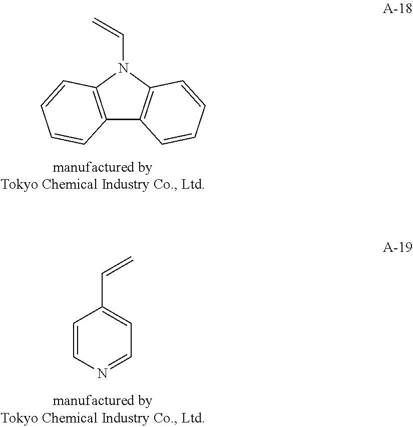

### Examples 20 to 29

Polymers P-24 to 31 were obtained in the same manner as in Example 1 except that SILAPLANE FM-0711 was replaced with Siloxane monomer B-1.

### Examples 30 to 33

Polymers P-30 to 33 were obtained in the same manner as in Example 20 except that 500 mg of the heterocyclic monomer was replaced with 250 mg of the heterocyclic monomer and 250 mg of a third monomer.

The charged amounts of the respective monomers, the number-average molecular weight (Mn) and weight-average molecular weight (Mw) of the obtained Polymers P1 to P31 are shown in Table 1 below. The number-average molecular weight and the weight-average molecular weight were measured using polystyrene as a standard substance using a high-speed GPC apparatus (manufactured by Tosoh Corporation).

<Synthesis of Host Material>

### Synthesis Example 19

### Synthesis of Intermediate 1

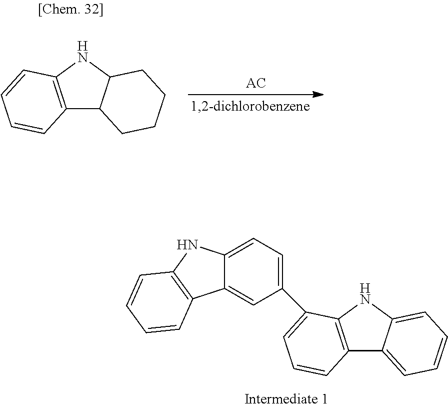 [SMILES: c1ccc2c(c1)NC1CCCCC21 ; c1ccc2c(c1)[nH]c1ccc(-c3cccc4c3[nH]c3ccccc34)cc12]

1,2,3,4-tetrahydrocarbazole(12 g, 72 mmol), activated carbon (12 g), and 120 mL of 1,2-dichlorobenzene were sequentially added into a 250 mL four-necked flask, and while air was blown into at the rate of 500 mL/min, the reaction mixture was stirred at 150° C. for 15 Hour. After cooling the reaction solution to room temperature, the reaction solution was filtered, the organic solvent was removed under reduced pressure, and purified by column chromatography. After removing the organic solvent under reduced pressure, 3.2 g (yield: 10%) of a yellow solid (Intermediate 1) was obtained.

### Synthesis Example 20

### Synthesis of9,9′-(p-tert-butylphenyl)-1,3-biscarbazole

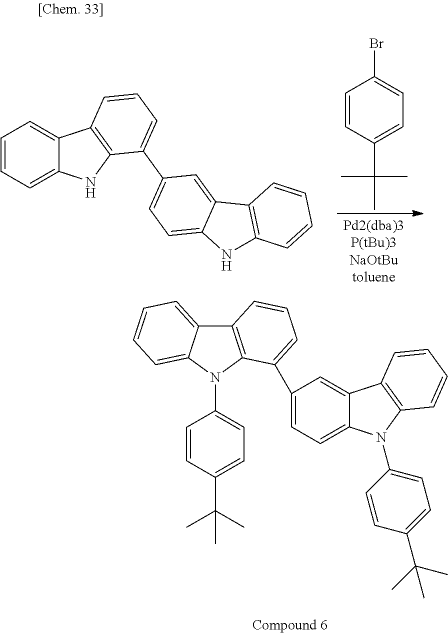

Under argon atmosphere, Intermediate 1 (0.836 g, 2.52 mmol), 1-bromo-4-t-butylbenzene (1.287 g, 6.04 mmol), tris(dibenzylidene)dipalladium (0.130 g, 0.13 mmol), tri-t-butylphosphine (0.076 g, 0.38 mmol), sodium-t-butoxide (0.725 g, 7.55 mmol) and 50 mL of toluene were sequentially added into a 200 mL three-necked flask, and the mixture was heated under reflux for 8 hours. After cooling the reaction solution to room temperature, water was added and an organic layer was collected with a separating funnel. The organic solvent was removed under reduced pressure and purified by silica gel chromatography, whereby 0.9 g (yield 60%) of a white solid (Compound 6) is obtained.

<Preparation of Electronic Material Composition>

Electronic material compositions including a light emitting material as an organic EL material were prepared using Polymers P-1 to33 of the present invention obtained in Examples to 31 and BYK-323 (aralkyl modified polysiloxane, manufactured by BYK Japan KK Polymer).

### Example 34

0.001 g of Polymer P-1 synthesized in Example 1 was dissolved in 9.9 g of tetralin, which is the solvent. Into the obtained solution, 0.04 g of tris[2-(p-tolyl) pyridine]iridium (Ir(mppy)₃) (manufactured by Lumtec Corp.) and 0.26 g of 9,9′-(p-tert-butylphenyl)-1,3-biscarbazole synthesized in Synthesis Example 20 were added and heated at 60° C. to prepare an electronic material composition.

### Examples 35 to 66

Electronic material compositions were prepared in the same manner as in Example 34 except that Polymer-1 was replaced with Polymers 2 to 33 synthesized in Examples 1 to 33.

### Comparative Example 1

An electronic material composition was prepared in the same manner as in Example 34 except that Polymer-1 was replaced with BYK-323.

<Evaluation>

The following various evaluations were performed with respect to the electronic material compositions prepared in Examples 34 to 66 and Comparative Example.

[Evaluation of Luminous Efficiency]

Organic EL elements were produced, and the luminous efficiency of the obtained organic light emitting elements was evaluated.

The organic EL elements were produced as follows.

Namely, a cleansed ITO substrate was irradiated with UV/O₃, and a film of poly(3,4-ethylenedioxythiophene)-poly(styrenesulfonic acid) (PEDOT-PSS) having a thickness of 45 nm was formed thereon by spin coating, and heated at 180° C. for 15 minutes in the air so as to form a hole injection layer. Subsequently, a film of 0.3 wt % xylene solution of HT-2 represented by the following formula was formed to a thickness of 10 nm on the hole injection layer by spin coating and dried at 200° C. for 30 minutes in a nitrogen atmosphere so as to form a hole transport layer. Next, a film of each of the electronic material compositions obtained in Examples 34 to 66 and Comparative Example was formed on the hole transport layer by spin coating, dried at 25° C. under reduced pressure of 1 Torr for 3 minute, and then dried at 110° C. for 15 minutes in a nitrogen atmosphere so as to form a light emitting layer having a thickness of 30 nm. Under the vacuum condition of 5×10⁻³ Pa, a film of ET-1 represented by the following formula having a thickness of 45 nm was formed as an electron transport layer, a film of lithium fluoride having a thickness of 0.5 nm was formed as an electron injection layer, and a film of aluminum having a thickness of 100 nm was formed as a cathode, subsequently. Finally, the substrate was delivered to a glove box and sealed with a glass substrate, thereby obtaining an organic light emitting element.

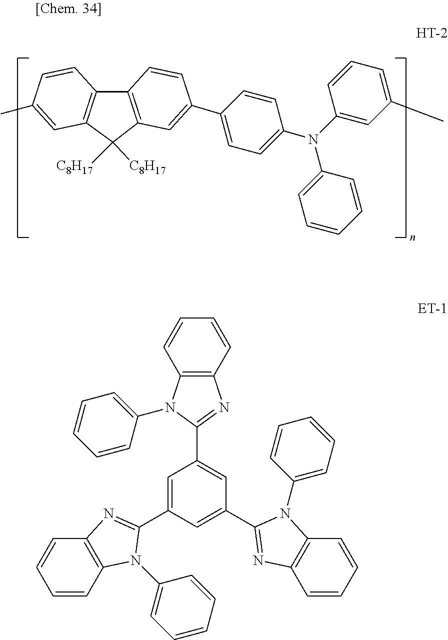

[Luminous Efficiency]

Using the produced organic EL element, a luminous efficiency was evaluated.

More specifically, the produced organic EL elements were connected to an external power source, and light emission from the organic EL elements was measured with BM-9 (manufactured by TOPCON Corporation). At this time, the luminous efficiency at the current value of 10 mA/cm² was calculated.

[Driving Stability]

In order to evaluate the driving stability, lifetime was evaluated using the produced organic EL elements.

More specifically, current of 10 mA/cm² was applied to each of the produced organic EL elements, and the luminance half-life thereof was measured with a photodiode type lifetime measurement apparatus (manufactured by System Engineers Co., Ltd.).

With respect to the luminous efficiency and the lifetime, the ratio of the value obtained in each of Examples to the value obtained in Comparative Example 1 was expressed in %, while the luminous efficiency and the lifetime of Comparative Example 1, which is a reference, each are expressed as 100%.

TABLE 1

| | | | Siloxane Monomer | | | | | | |
|---|---|---|---|---|---|---|---|---|---|
| | Heterocycic monomer | | FM0711 | B-1 | Third monomer | | | | |
| | | Charged | charged | charged | | Charged | | | |
| Example | Monomer | amount (g) | amount (g) | amount (g) | Monomer | amount (g) | Polymer | Mn | Mw |
| Example 1 | A-1 | 0.5 | 0.28 | | | | P-1 | 8900 | 21000 |
| Example 2 | A-2 | 0.5 | 0.28 | | | | P-2 | 5800 | 13000 |
| Example 3 | A-3 | 0.5 | 0.28 | | | | P-3 | 11000 | 23000 |
| Example 4 | A-4 | 0.5 | 0.19 | | | | P-4 | 7100 | 16000 |
| Example 5 | A-5 | 0.5 | 0.17 | | | | P-5 | 5100 | 13000 |
| Example 6 | A-6 | 0.5 | 0.17 | | | | P-6 | 8300 | 19000 |
| Example 7 | A-7 | 0.5 | 0.13 | | | | P-7 | 6500 | 16000 |
| Example 8 | A-8 | 0.5 | 0.13 | | | | P-8 | 9800 | 24000 |
| Example 9 | A-9 | 0.5 | 0.11 | | | | P-9 | 8600 | 19000 |
| Example 10 | A-10 | 0.5 | 0.12 | | | | P-10 | 5900 | 13000 |
| Example 11 | A-11 | 0.5 | 0.12 | | | | P-11 | 5500 | 13000 |
| Example 12 | A-12 | 0.5 | 0.10 | | | | P-12 | 8300 | 19000 |
| Example 13 | A-13 | 0.5 | 0.11 | | | | P-13 | 10700 | 25000 |
| Example 14 | A-14 | 0.5 | 0.15 | | | | P-14 | 4900 | 11000 |
| Example 15 | A-15 | 0.5 | 0.12 | | | | P-15 | 6100 | 14000 |
| Example 16 | A-16 | 0.5 | 0.11 | | | | P-16 | 10400 | 23000 |
| Example 17 | A-17 | 0.5 | 0.10 | | | | P-17 | 9200 | 20000 |
| Example 18 | A-18 | 0.5 | 0.26 | | | | P-18 | 10000 | 22000 |
| Example 19 | A-19 | 0.5 | 0.48 | | | | P-19 | 11800 | 26000 |
| Example 20 | A-18 | 0.5 | | 0.28 | | | P-20 | 5200 | 13000 |
| Example 21 | A-5 | 0.5 | | 0.19 | | | P-21 | 4800 | 10000 |
| Example 22 | A-6 | 0.5 | | 0.15 | | | P-22 | 6500 | 14000 |
| Example 23 | A-8 | 0.5 | | 0.14 | | | P-23 | 7200 | 17000 |
| Example 24 | A-12 | 0.5 | | 0.11 | | | P-24 | 7700 | 15000 |
| Example 25 | A-13 | 0.5 | | 0.12 | | | P-25 | 8100 | 19000 |
| Example 26 | A-14 | 0.5 | | 0.16 | | | P-26 | 5900 | 12000 |
| Example 27 | A-15 | 0.5 | | 0.13 | | | P-27 | 7400 | 18000 |
| Example 28 | A-16 | 0.5 | | 0.12 | | | P-28 | 6300 | 14000 |
| Example 29 | A-17 | 0.5 | | 0.10 | | | P-29 | 7500 | 16000 |
| Example 30 | A-18 | 0.25 | | 0.41 | stylene | 0.25 | P-30 | 8100 | 20000 |
| Example 31 | A-5 | 0.25 | | 0.36 | stylene | 0.25 | P-31 | 7600 | 22000 |
| Example 32 | A-13 | 0.25 | | 0.16 | A-4 | 0.25 | P-32 | 7300 | 19000 |
| Example 33 | A-17 | 0.25 | | 0.15 | A-4 | 0.25 | P-33 | 7400 | 18000 |

TABLE 2

| Electronic Material | | Luminous | |
|---|---|---|---|
| Composition | Polymer | Efficiency (%) | Lifetime (%) |
| Example 34 | P-1 | 214 | 139 |
| Example 35 | P-2 | 178 | 107 |
| Example 36 | P-3 | 191 | 156 |
| Example 37 | P-4 | 230 | 169 |
| Example 38 | P-5 | 167 | 123 |
| Example 39 | P-6 | 222 | 133 |
| Example 40 | P-7 | 206 | 165 |
| Example 41 | P-8 | 228 | 160 |
| Example 42 | P-9 | 199 | 142 |
| Example 43 | P-10 | 185 | 182 |
| Example 44 | P-11 | 211 | 192 |
| Example 45 | P-12 | 227 | 186 |
| Example 46 | P-13 | 203 | 168 |
| Example 47 | P-14 | 209 | 191 |
| Example 48 | P-15 | 214 | 179 |
| Example 49 | P-16 | 218 | 199 |
| Example 50 | P-17 | 226 | 177 |
| Example 51 | P-18 | 230 | 145 |
| Example 52 | P-19 | 183 | 121 |
| Example 53 | P-20 | 107 | 112 |
| Example 54 | P-21 | 168 | 184 |
| Example 55 | P-22 | 209 | 199 |
| Example 56 | P-23 | 227 | 203 |
| Example 57 | P-24 | 230 | 221 |
| Example 58 | P-25 | 218 | 253 |
| Example 59 | P-26 | 205 | 201 |
| Example 60 | P-27 | 212 | 209 |
| Example 61 | P-28 | 216 | 257 |
| Example 62 | P-29 | 228 | 265 |
| Example 63 | P-30 | 107 | 112 |
| Example 64 | P-31 | 129 | 123 |
| Example 65 | P-32 | 230 | 283 |
| Example 66 | P-33 | 228 | 291 |
| Comparative | BYK-323 | 100 | 100 |
| Example 1 | | | |

As is apparent from the results in Table 2, in the case where a coating film was formed by using each of the electronic material compositions of Examples 34 to 66, luminous efficiency and lifetime were improved in comparison with Comparative Example. That is, it can be seen that the use of the electronic material composition of the present invention enables the elements to exhibit excellent luminous efficiency and driving stability.

1. A copolymer, which is obtained by copolymerizing a monomer represented by General Formula (1), and at least a monomer represented by General Formula (3) or General Formula (4):
[Chem.1]
A₁-L₁-B₁ (1)
(in General Formula (1), A₁ is a polymerizable reaction group, L₁ is a single bond, or a substituted or unsubstituted aromatic hydrocarbon or condensed aromatic hydrocarbon group each having 6 to 30 carbon atoms, and B₁ is represented by General Formula (2): 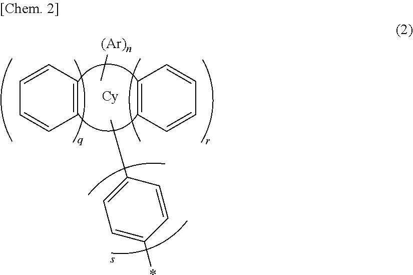
in General Formula (2), a Cy ring represents a 5-membered or 6-membered aromatic ring which contains 1 to 3 nitrogen atoms and 0 to 1 oxygen atom, q, r, and s each independently represent 0 or 1, n is an integer of 0 to 2, Ar is a phenyl group or a biphenyl group, which each may have an alkyl group having 1 to 8 carbon atoms as a substituent, and * represents a linking to L₁ in General Formula (1)): 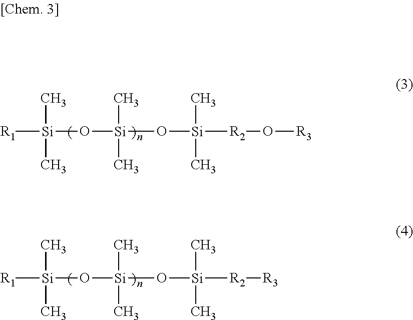
(in General Formulas (3) and (4), n represents 1 to 1,000, R₁ and R₂ represent a hydrocarbon group that may include an ether bonding, and R₃ represents a vinyl group or an organic group having a vinyl group).

2. The copolymer according to claim 1,
wherein in General Formula (2), the A ring is at least one selected from General Formulas (5) to (7): 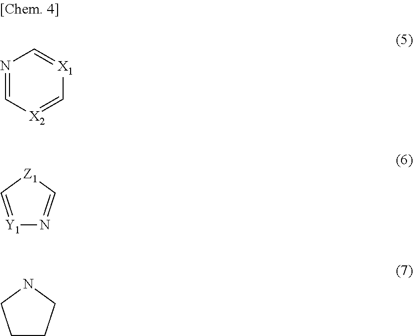
(in General Formulas (5), (6), and (7), X₁, X₂, and X₃ each independently represent a carbon atom or a nitrogen atom, Y₁ is a carbon atom or a nitrogen atom, and Z₁ is a nitrogen atom or an oxygen atom).

3. A composition comprising the polymer according to claim 1.

4. An electronic material composition comprising the polymer according to claim 1.

5. An electronic element comprising the composition according to claim 3.

6. A composition comprising the polymer according to claim 2.

7. An electronic material composition comprising the polymer according to claim 2.

8. The electronic material composition according to claim 4.
